(19) United States
(12) Patent Application Publication
(10) Pub. No.: US 2024/0018168 A1
(43) Pub. Date: Jan. 18, 2024

(54) COMPOUND WITH MULTIPLE RESONANCE CHARACTERISTICS AND ORGANIC ELECTROLUMINESCENT DEVICE CONTAINING COMPOUND

(71) Applicant: SHIJIAZHUANG CHENGZHI YONGHUA DISPLAY MATERIAL CO., LTD., Shijiazhuang (CN)

(72) Inventors: Zaifeng XIE, Shijiazhuang (CN); Tianyu WEI, Shijiazhuang (CN); Yubin XING, Shijiazhuang (CN); Lingwei XU, Shijiazhuang (CN); Songyuan LIU, Shijiazhuang (CN)

(73) Assignee: SHIJIAZHUANG CHENGZHI YONGHUA DISPLAY MATERIAL CO., LTD., Shijiazhuang (CN)

(21) Appl. No.: 18/371,267

(22) Filed: Sep. 21, 2023

(30) Foreign Application Priority Data
Sep. 23, 2022 (CN) 202211162035.6

(51) Int. Cl. C07F 5/02; H10K 85/60; C09K 11/02

(52) U.S. Cl. CPC C07F 5/027; H10K 85/658; H10K 85/631; H10K 85/6574; H10K 85/6576; H10K 85/615; C09K 11/02; C07B 2200/05

(57) ABSTRACT

The present invention discloses a compound with multiple resonance characteristics and an organic electroluminescent device containing the compound. In the present invention, by introducing a bridged cyclic alkyl group, the rigidity of the compound is increased, the thermal stability and glass transition temperature of a host material can be effectively improved while the dispersion of guest molecules in the material is maintained, and the lifetime of a blue-light device is significantly prolonged. The compound provided by the present invention is suitable for blue host/dopant systems and organic electroluminescent devices of blue-series AM-OLEDs, and organic electroluminescent devices containing the compound have a higher external quantum efficiency, a lower driving voltage, and a particularly excellent lifetime.

### TECHNICAL FIELD

The present invention belongs to the technical field of OLEDs, and in particular involves a compound with multiple resonance characteristics and an organic electroluminescent device containing the compound.

### BACKGROUND ART

In recent years, optoelectronic devices based on organic materials have become more and more popular. Examples of such organic optoelectronic devices include organic light-emitting diodes (OLEDs), organic field effect transistors, organic photovoltaic cells, organic sensors, etc. Among them, OLEDs are developing particularly rapidly and has achieved commercial success in the field of information display. OLEDs can provide red, green and blue colors with high saturation, and full-color display devices made thereof do not need an additional backlight source and have the advantages of dazzling colors, short response time, wide color gamut, high contrast, etc.

The core of an OLED device is a thin film structure containing a variety of organic functional materials. Common functional organic materials include hole injection materials, hole transport materials, hole blocking materials, electron injection materials, electron transport materials, electron blocking materials, light-emitting host materials, light-emitting guests (dyes), etc. When energized, electrons and holes are respectively injected into, transported to and recombined in a light-emitting region, thus generating excitons and emitting light. Organic luminescent materials, the core of OLED display technologies, realize full color gamut based on mixed red, green and blue materials. The development of new luminescent materials is the driving force to promote the continuous progress of electroluminescent technologies and is also a research hotspot in the organic electroluminescent industry. The development of new blue-light organic electroluminescent materials realizes high luminous efficiency and better lifetime of devices. In addition, the development of blue-light luminescent materials focuses on blue-light luminescent materials with a narrow peak width at half height and a high color purity.

At present, by means of the multiple resonance effect (MR effect) and the opposite vibration of boron atoms relative to heteroatoms such as nitrogen and oxygen, polycyclic aromatic compounds formed by the condensation of multiple aromatic rings via boron atoms and heteroatoms such as nitrogen and oxygen are constructed, that is, special rigid material systems containing boron atoms and nitrogen-oxygen heteroatoms are prepared. Such fluorescent molecules have a high radiative transition rate, a narrow peak width at half height, and a high color purity, but the performance thereof in terms of device life and luminous efficiency is not particularly ideal; in addition, the industrialization process of this technology is still confronted with many crucial problems. Therefore, the development of new materials has always been an urgent problem to be solved by those skilled in the art.

Usually, researchers add an alkyl substituent to a guest luminescent material to facilitate better dispersion thereof in the host material, which can effectively reduce the local aggregation of guest molecules. This in turn avoids a quenching effect caused by an excessively high exciton concentration, thus improving the luminous efficiency. However, due to the flexibility of alkyl or cycloalkyl, problems such as reduced glass transition temperature of molecules and deteriorated thermal stability have been caused.

### SUMMARY OF THE INVENTION

In view of the above problems existing in the prior art, the present invention provides a compound with multiple resonance characteristics and an organic electroluminescent device containing the compound.

In order to achieve the above objective, the technical solution used by the present invention comprises the following content:

In a first aspect of the present invention, there is provided a compound with multiple resonance characteristics, wherein the compound has a general structural formula as represented by Formula I:

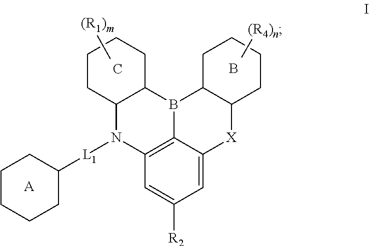

wherein ring A represents a substituted or unsubstituted bridged cyclic alkyl group with a carbon atom number of C₄-C₃₀ or a substituted or unsubstituted bridged cyclic alkenyl group with a carbon atom number of C₄-C₃₀; ring B and ring C each independently represent one of a substituted or unsubstituted aryl group with a carbon atom number of C₆-C₆₀, a substituted or unsubstituted heteroaryl group with a carbon atom number of C₄-C₆₀, a substituted or unsubstituted fused cycloaryl group with a carbon atom number of C₆-C₆₀, and a substituted or unsubstituted fused heterocycloaryl group with a carbon atom number of C₅-C₆₀;
X represents N-L₂-R₃ or O;
L₁ and L₂ each independently represent a single bond or a substituted or unsubstituted aryl group with a carbon atom number of C₆-C₂₀;
R₁ and R₄ each independently represent one of hydrogen, deuterium, halogen, a substituted or unsubstituted alkyl group with a carbon atom number of C₁-C₃₀, a substituted or unsubstituted alkoxy group with a carbon atom number of C₁-C₃₀, a substituted or unsubstituted alkenyl group with a carbon atom number of C₂-C₃₀, a substituted or unsubstituted cycloalkyl group with a carbon atom number of C₃-C₃₀, a substituted or unsubstituted bridged cyclic alkyl group with a carbon atom number of C₄-C₃₀, a substituted or unsubstituted aryl group with a carbon atom number of C₆-C₆₀, a substituted or unsubstituted heteroaryl group with a carbon atom number of C₆-C₆₀, a substituted or unsubstituted fused cycloaryl group with a carbon atom number of C₆-C₆₀, a substituted or unsubstituted fused heterocycloaryl group with a carbon atom number of C₅-C₆₀, and a substituted or unsubstituted arylamino group with a carbon atom number of C₆-C₆₀;
m and n each independently represent 1, 2, 3, or 4; when m and n are 2, 3, or 4, R₁ and R₄ can be the same or different;
R₂ represents one of hydrogen, deuterium, halogen, a substituted or unsubstituted alkyl group with a carbon atom number of C₁-C₃₀, a substituted or unsubstituted cycloalkyl group with a carbon atom number of C₃-C₃₀, a substituted or unsubstituted bridged cyclic alkyl group with a carbon atom number of C₄-C₃₀, a substituted or unsubstituted bridged cyclic alkenyl group with a carbon atom number of C₄-C₃₀, a substituted or unsubstituted aryl group with a carbon atom number of C₆-C₆₀, a substituted or unsubstituted heteroaryl group with a carbon atom number of C₆-C₆₀, a substituted or unsubstituted fused cycloaryl group with a carbon atom number of C₆-C₆₀, a substituted or unsubstituted fused heterocycloaryl group with a carbon atom number of C₅-C₆₀, and a substituted or unsubstituted amino group;
R₃ represents one of hydrogen, deuterium, halogen, a substituted or unsubstituted alkyl group with a carbon atom number of C₁-C₃₀, a substituted or unsubstituted alkenyl group with a carbon atom number of C₂-C₃₀, a substituted or unsubstituted cycloalkyl group with a carbon atom number of C₃-C₃₀, a substituted or unsubstituted bridged cyclic alkyl group with a carbon atom number of C₄-C₃₀, a substituted or unsubstituted aryl group with a carbon atom number of C₆-C₆₀, a substituted or unsubstituted heteroaryl group with a carbon atom number of C₆-C₆₀, a substituted or unsubstituted fused cycloaryl group with a carbon atom number of C₆-C₆₀, and a substituted or unsubstituted fused heterocycloaryl group with a carbon atom number of C₅-C₆₀; R₃ can be connected to ring B to form a ring;
substituents in ring A, ring B, ring C, R₁, R₂, R₃, R₄, L₁, and L₂ may be the same or different and are each independently selected from one of deuterium, halogen, cyano, an alkyl group with a carbon atom number of C₁-C₁₀, an aryl group with a carbon atom number of C₆-C₆₀, a fused cycloaryl group with a carbon atom number of C₆-C₆₀, and a cycloalkyl group with a carbon atom number of C₃-C₃₀, wherein two or more substituents can be connected to each other to form an aliphatic ring, an aromatic ring, or a condensed ring; and each hydrogen on the compound represented by Formula I can be independently replaced by deuterium.

Furthermore, the amino group is selected from one of a substituted or unsubstituted alkylamino group with a carbon atom number of C₁-C₁₀, a substituted or unsubstituted arylamino group with a carbon atom number of C₆-C₂₀, a substituted or unsubstituted aralkylamino group with a carbon atom number of C₆-C₂₀, and a substituted or unsubstituted heteroarylamino group with a carbon atom number of C₂-C₂₄.

Furthermore, the ring formed by connecting R₃ to ring B is a substituted or unsubstituted aliphatic ring group, a substituted or unsubstituted aromatic ring, a substituted or unsubstituted heteroaromatic ring, or a substituted or unsubstituted condensed ring.

Furthermore, the compound of Formula I is selected from one of the following structures represented by Formulas I-1 to I-6:

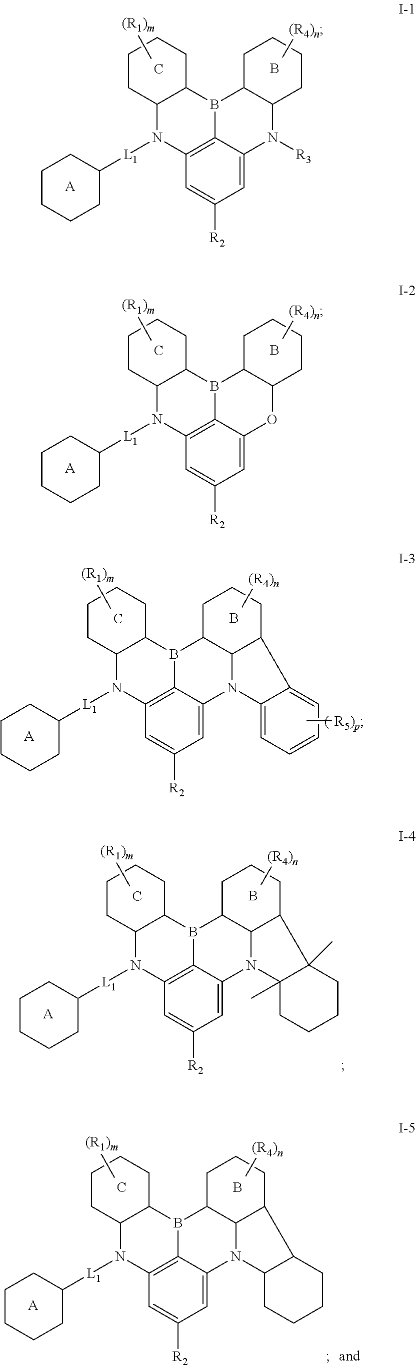

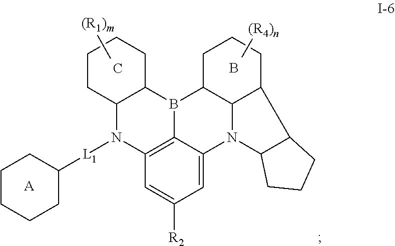

wherein R₅ represents a substituted or unsubstituted alkyl group with a carbon atom number of C₁-C₃₀, p represents 0, 1, 2, 3, or 4; and when p represents 2, 3, or 4, p can be the same or different.

Furthermore, ring A represents

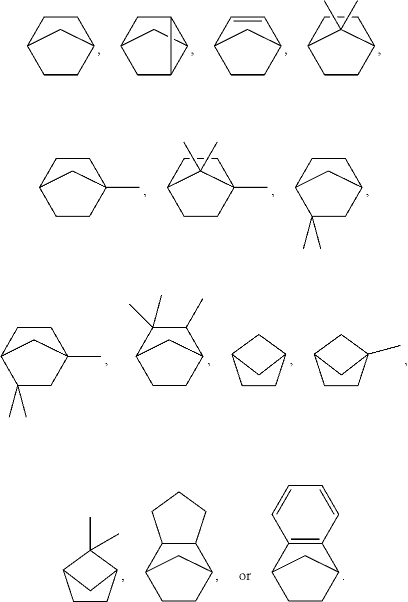

Furthermore, ring B and ring C each independently represent

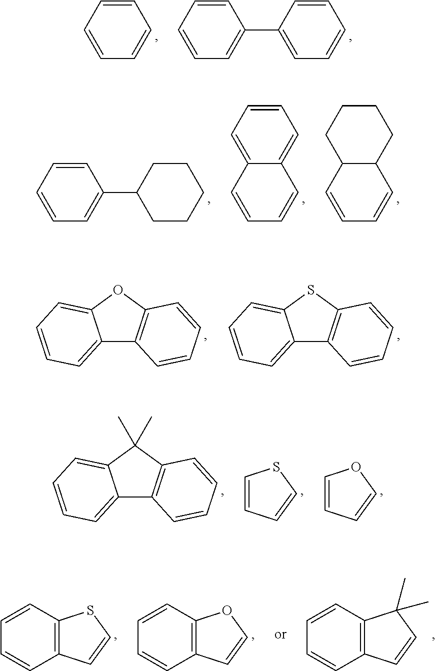

wherein any nonadjacent C in each of the above structures can be each independently replaced by N, and any hydrogen can be each independently replaced by fluorine, deuterium, cyano, linear alkyl, branched alkyl, cycloalkyl, aryl, heteroaryl, or arylamino.

Furthermore, R₁ and R₄ each independently represent a substituted or unsubstituted linear alkyl or branched alkyl group with a carbon atom number of C₁-C₁₀,

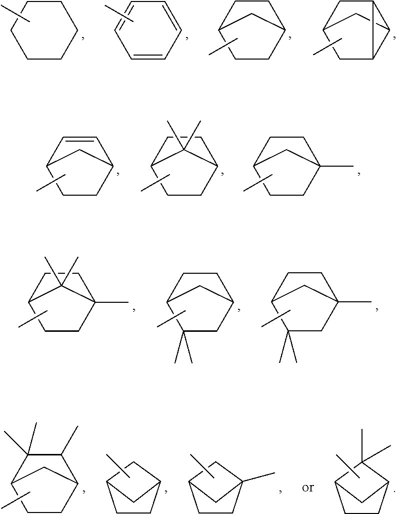

Furthermore, R₂ represents a substituted or unsubstituted linear alkyl or branched alkyl group with a carbon atom number of C₁-C₁₀,

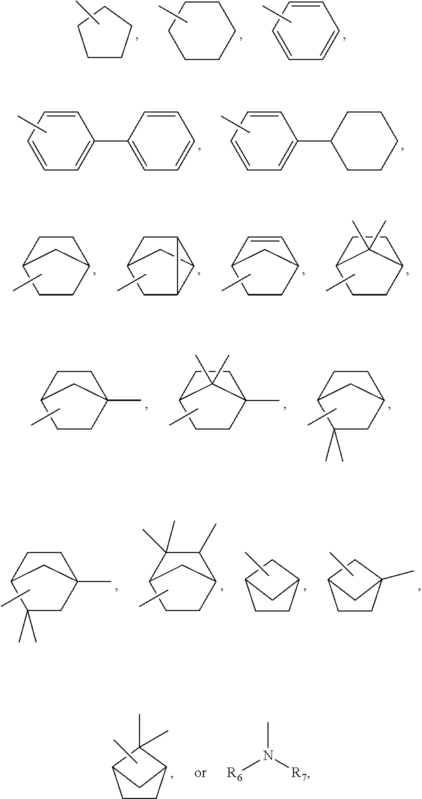

wherein R₆ and R₇ each independently represent a substituted or unsubstituted alkyl group with a carbon atom number of C₁-C₁₀, a substituted or unsubstituted cycloalkyl group with a carbon atom number of C₃-C₁₅, and a substituted or unsubstituted aryl group with a carbon atom number of C₆-C₂₀.

Furthermore, R₃ represents a substituted or unsubstituted linear alkyl or branched alkyl group with a carbon atom number of C₁-C₁₀, a substituted or unsubstituted alkenyl group with a carbon atom number of C₂-C₁₀,

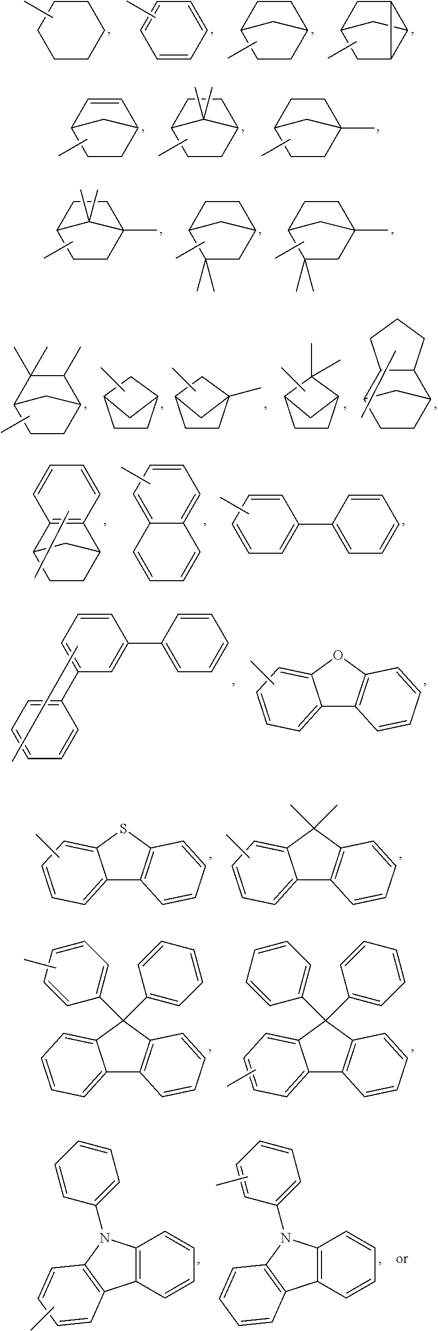

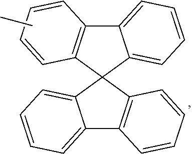

wherein any hydrogen in each of the above structures can be each independently replaced by fluorine, deuterium, linear alkyl, branched alkyl, cycloalkyl, or phenyl.

Furthermore, the compound represented by Formula I is selected from any one of the following compounds:

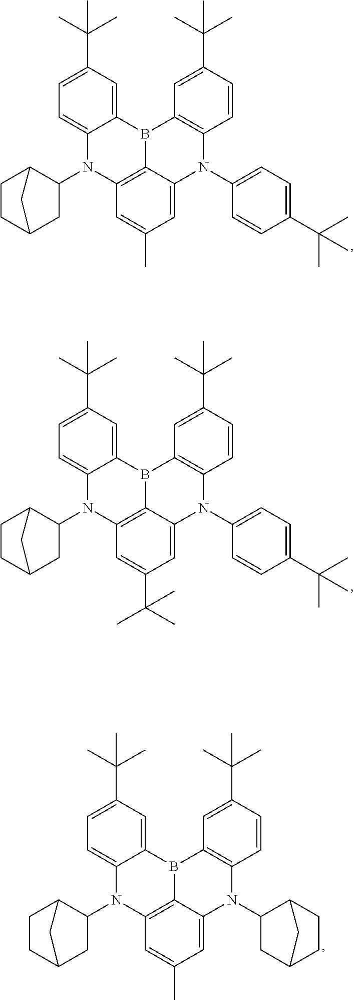 [SMILES: Cc1cc2c3c(c1)N(C1CC4CCC1C4)c1ccc(C(C)(C)C)cc1B3c1cc(C(C)(C)C)ccc1N2c1ccc(C(C)(C)C)cc1 ; CC(C)(C)c1ccc(N2c3ccc(C(C)(C)C)cc3B3c4cc(C(C)(C)C)ccc4N(C4CC5CCC4C5)c4cc(C(C)(C)C)cc2c43)cc1 ; Cc1cc2c3c(c1)N(C1CC4CCC1C4)c1ccc(C(C)(C)C)cc1B3c1cc(C(C)(C)C)ccc1N2C1CC2CCC1C2]

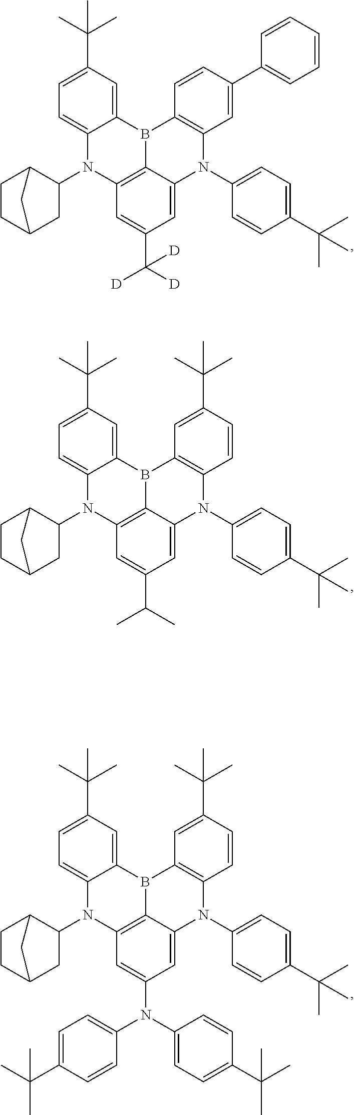 [SMILES: [2H]C([2H])([2H])c1cc2c3c(c1)N(C1CC4CCC1C4)c1ccc(C(C)(C)C)cc1B3c1ccc(-c3ccccc3)cc1N2c1ccc(C(C)(C)C)cc1 ; CC(C)c1cc2c3c(c1)N(C1CC4CCC1C4)c1ccc(C(C)(C)C)cc1B3c1cc(C(C)(C)C)ccc1N2c1ccc(C(C)(C)C)cc1 ; CC(C)(C)c1ccc(N(c2ccc(C(C)(C)C)cc2)c2cc3c4c(c2)N(C2CC5CCC2C5)c2ccc(C(C)(C)C)cc2B4c2cc(C(C)(C)C)ccc2N3c2ccc(C(C)(C)C)cc2)cc1]

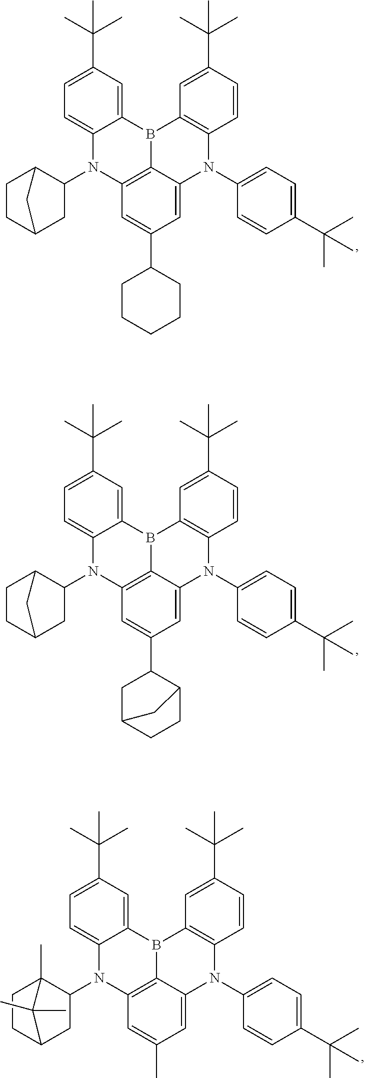

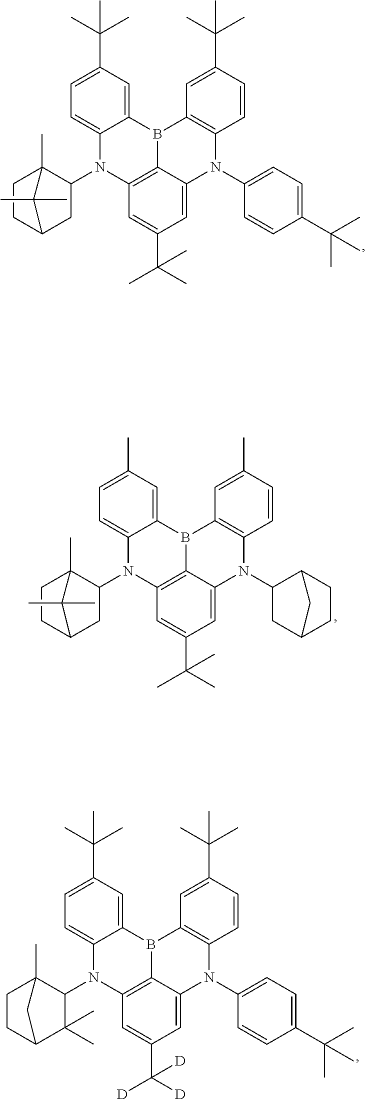

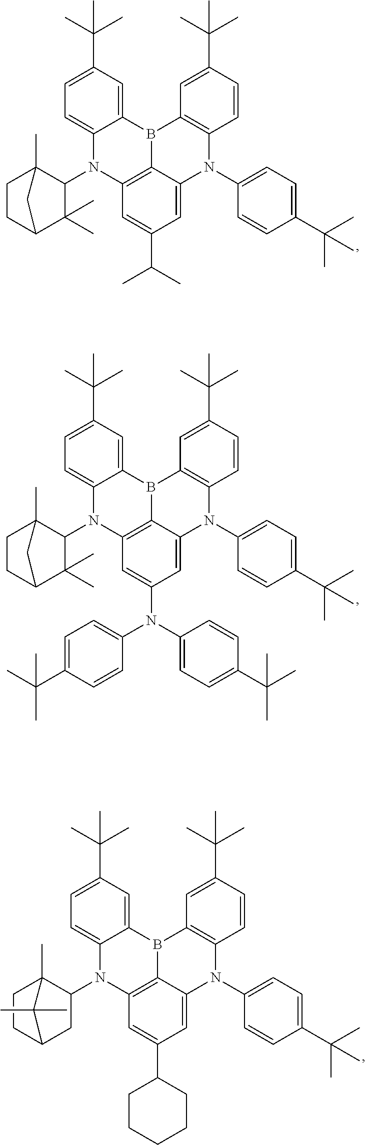

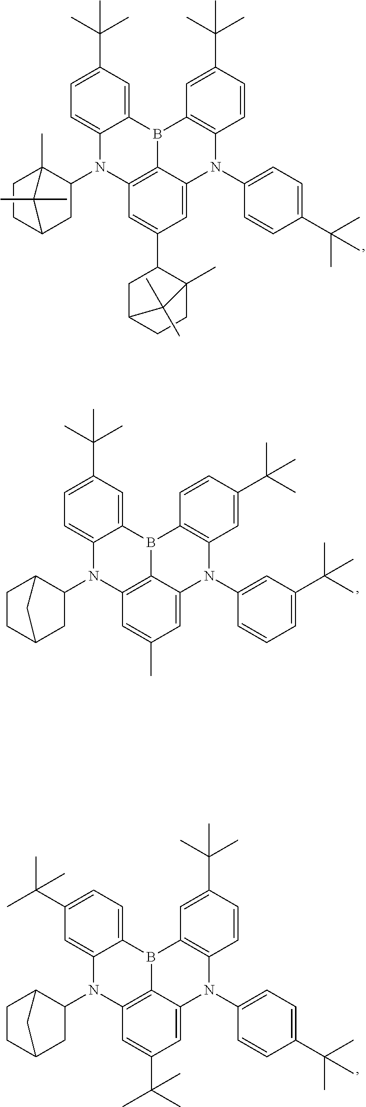 [SMILES: CC(C)(C)c1ccc(N2c3ccc(C(C)(C)C)cc3B3c4cc(C(C)(C)C)ccc4N(C4CC5CCC4(C)C5(C)C)c4cc(C5CC6CCC5(C)C6(C)C)cc2c43)cc1 ; Cc1cc2c3c(c1)N(C1CC4CCC1C4)c1ccc(C(C)(C)C)cc1B3c1ccc(C(C)(C)C)cc1N2c1cccc(C(C)(C)C)c1 ; CC(C)(C)c1ccc(N2c3ccc(C(C)(C)C)cc3B3c4ccc(C(C)(C)C)cc4N(C4CC5CCC4C5)c4cc(C(C)(C)C)cc2c43)cc1]

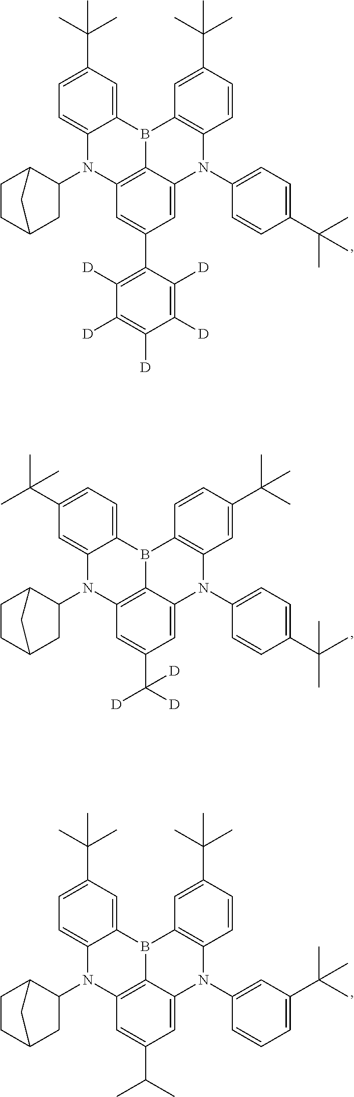 [SMILES: [2H]c1c([2H])c([2H])c(-c2cc3c4c(c2)N(C2CC5CCC2C5)c2ccc(C(C)(C)C)cc2B4c2cc(C(C)(C)C)ccc2N3c2ccc(C(C)(C)C)cc2)c([2H])c1[2H] ; [2H]C([2H])([2H])c1cc2c3c(c1)N(C1CC4CCC1C4)c1cc(C(C)(C)C)ccc1B3c1ccc(C(C)(C)C)cc1N2c1ccc(C(C)(C)C)cc1 ; CC(C)c1cc2c3c(c1)N(C1CC4CCC1C4)c1ccc(C(C)(C)C)cc1B3c1cc(C(C)(C)C)ccc1N2c1cccc(C(C)(C)C)c1]

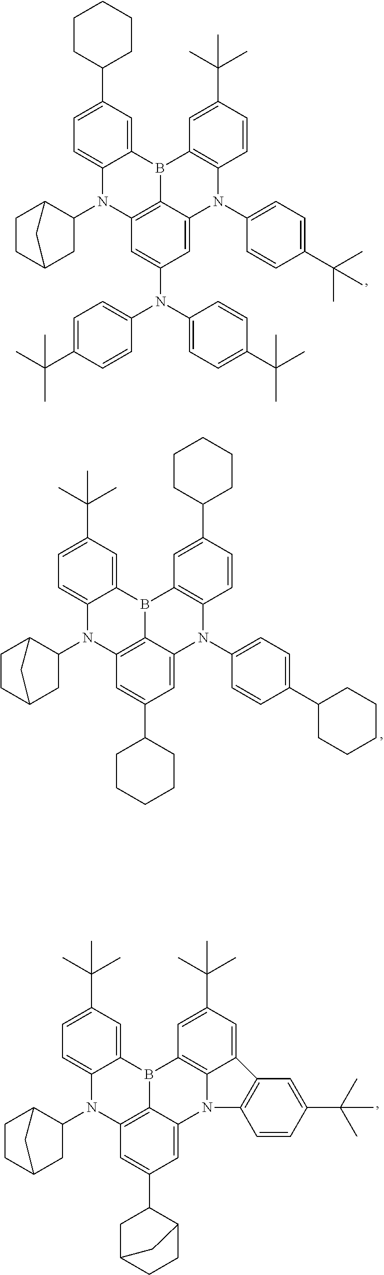 [SMILES: CC(C)(C)c1ccc(N(c2ccc(C(C)(C)C)cc2)c2cc3c4c(c2)N(C2CC5CCC2C5)c2ccc(C5CCCCC5)cc2B4c2cc(C(C)(C)C)ccc2N3c2ccc(C(C)(C)C)cc2)cc1 ; CC(C)(C)c1ccc2c(c1)B1c3cc(C4CCCCC4)ccc3N(c3ccc(C4CCCCC4)cc3)c3cc(C4CCCCC4)cc(c31)N2C1CC2CCC1C2 ; CC(C)(C)c1ccc2c(c1)B1c3c(cc(C4CC5CCC4C5)cc3-n3c4ccc(C(C)(C)C)cc4c4cc(C(C)(C)C)cc1c43)N2C1CC2CCC1C2]

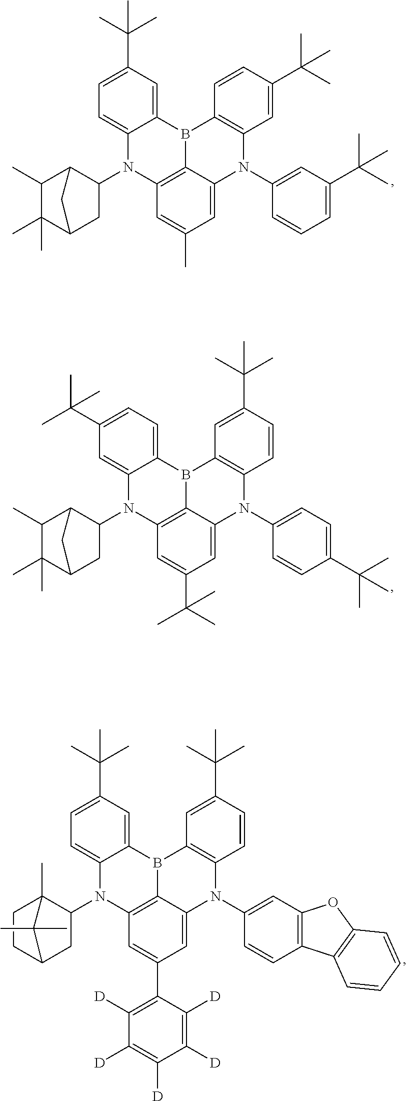

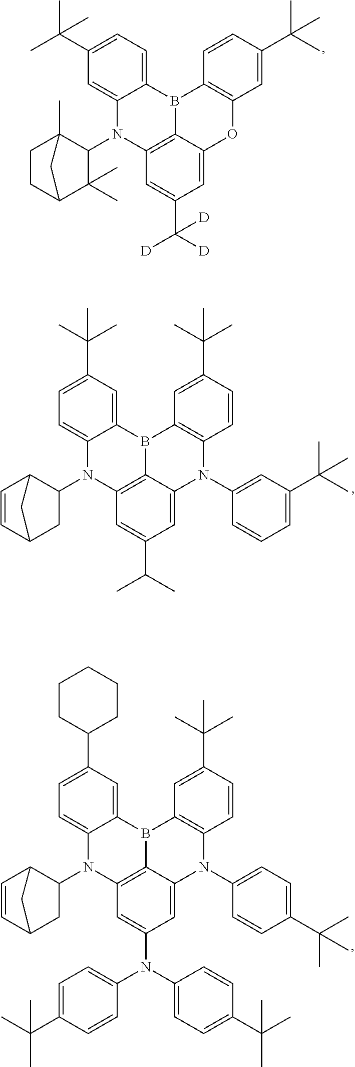 [SMILES: [2H]C([2H])([2H])c1cc2c3c(c1)N(C1C4(C)CCC(C4)C1(C)C)c1cc(C(C)(C)C)ccc1B3c1ccc(C(C)(C)C)cc1O2 ; CC(C)c1cc2c3c(c1)N(C1CC4C=CC1C4)c1ccc(C(C)(C)C)cc1B3c1cc(C(C)(C)C)ccc1N2c1cccc(C(C)(C)C)c1 ; CC(C)(C)c1ccc(N(c2ccc(C(C)(C)C)cc2)c2cc3c4c(c2)N(C2CC5C=CC2C5)c2ccc(C5CCCCC5)cc2B4c2cc(C(C)(C)C)ccc2N3c2ccc(C(C)(C)C)cc2)cc1]

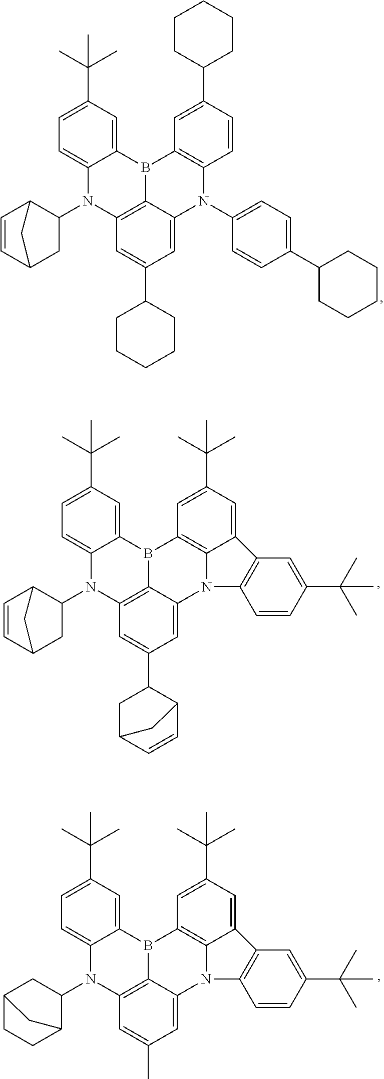 [SMILES: CC(C)(C)c1ccc2c(c1)B1c3cc(C4CCCCC4)ccc3N(c3ccc(C4CCCCC4)cc3)c3cc(C4CCCCC4)cc(c31)N2C1CC2C=CC1C2 ; CC(C)(C)c1ccc2c(c1)B1c3c(cc(C4CC5C=CC4C5)cc3-n3c4ccc(C(C)(C)C)cc4c4cc(C(C)(C)C)cc1c43)N2C1CC2C=CC1C2 ; Cc1cc2c3c(c1)-n1c4ccc(C(C)(C)C)cc4c4cc(C(C)(C)C)cc(c41)B3c1cc(C(C)(C)C)ccc1N2C1CC2CCC1C2]

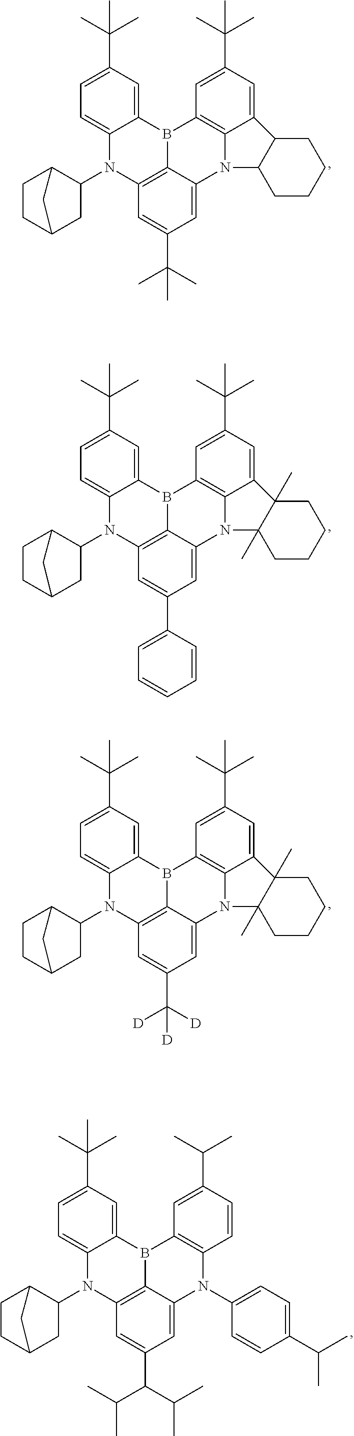 [SMILES: CC(C)(C)c1ccc2c(c1)B1c3cc(C(C)(C)C)cc4c3N(c3cc(C(C)(C)C)cc(c31)N2C1CC2CCC1C2)C1CCCCC41 ; CC(C)(C)c1ccc2c(c1)B1c3cc(C(C)(C)C)cc4c3N(c3cc(-c5ccccc5)cc(c31)N2C1CC2CCC1C2)C1(C)CCCCC41C ; [2H]C([2H])([2H])c1cc2c3c(c1)N1c4c(cc(C(C)(C)C)cc4C4(C)CCCCC14C)B3c1cc(C(C)(C)C)ccc1N2C1CC2CCC1C2 ; CC(C)c1ccc(N2c3ccc(C(C)C)cc3B3c4cc(C(C)(C)C)ccc4N(C4CC5CCC4C5)c4cc(C(C(C)C)C(C)C)cc2c43)cc1]

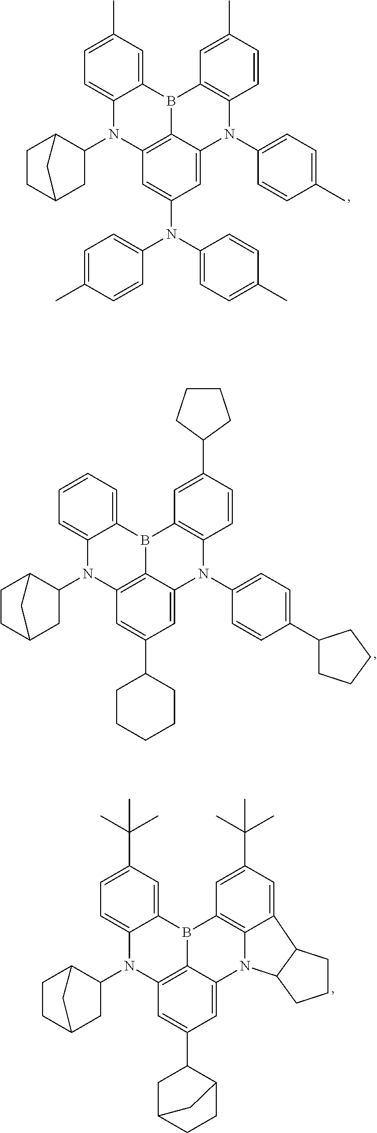 [SMILES: Cc1ccc(N(c2ccc(C)cc2)c2cc3c4c(c2)N(C2CC5CCC2C5)c2ccc(C)cc2B4c2cc(C)ccc2N3c2ccc(C)cc2)cc1 ; c1ccc2c(c1)B1c3cc(C4CCCC4)ccc3N(c3ccc(C4CCCC4)cc3)c3cc(C4CCCCC4)cc(c31)N2C1CC2CCC1C2 ; CC(C)(C)c1ccc2c(c1)B1c3cc(C(C)(C)C)cc4c3N(c3cc(C5CC6CCC5C6)cc(c31)N2C1CC2CCC1C2)C1CCCC41]

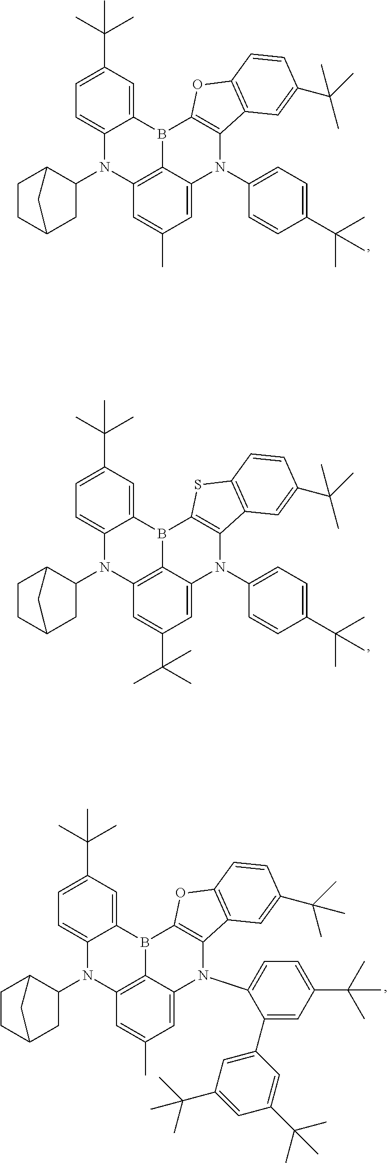 [SMILES: Cc1cc2c3c(c1)N(C1CC4CCC1C4)c1ccc(C(C)(C)C)cc1B3c1oc3ccc(C(C)(C)C)cc3c1N2c1ccc(C(C)(C)C)cc1 ; CC(C)(C)c1ccc(N2c3cc(C(C)(C)C)cc4c3B(c3cc(C(C)(C)C)ccc3N4C3CC4CCC3C4)c3sc4ccc(C(C)(C)C)cc4c32)cc1 ; Cc1cc2c3c(c1)N(C1CC4CCC1C4)c1ccc(C(C)(C)C)cc1B3c1oc3ccc(C(C)(C)C)cc3c1N2c1ccc(C(C)(C)C)cc1-c1cc(C(C)(C)C)cc(C(C)(C)C)c1]

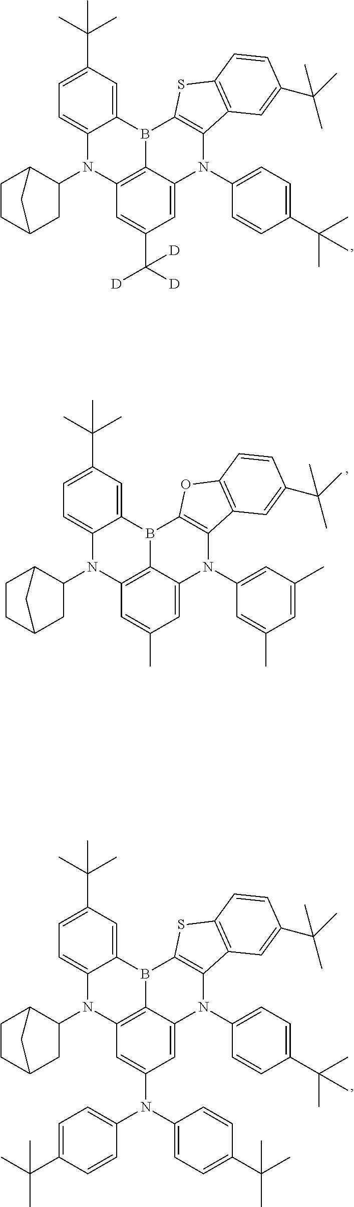 [SMILES: [2H]C([2H])([2H])c1cc2c3c(c1)N(C1CC4CCC1C4)c1ccc(C(C)(C)C)cc1B3c1sc3ccc(C(C)(C)C)cc3c1N2c1ccc(C(C)(C)C)cc1 ; Cc1cc(C)cc(N2c3cc(C)cc4c3B(c3cc(C(C)(C)C)ccc3N4C3CC4CCC3C4)c3oc4ccc(C(C)(C)C)cc4c32)c1 ; CC(C)(C)c1ccc(N(c2ccc(C(C)(C)C)cc2)c2cc3c4c(c2)N(C2CC5CCC2C5)c2ccc(C(C)(C)C)cc2B4c2sc4ccc(C(C)(C)C)cc4c2N3c2ccc(C(C)(C)C)cc2)cc1]

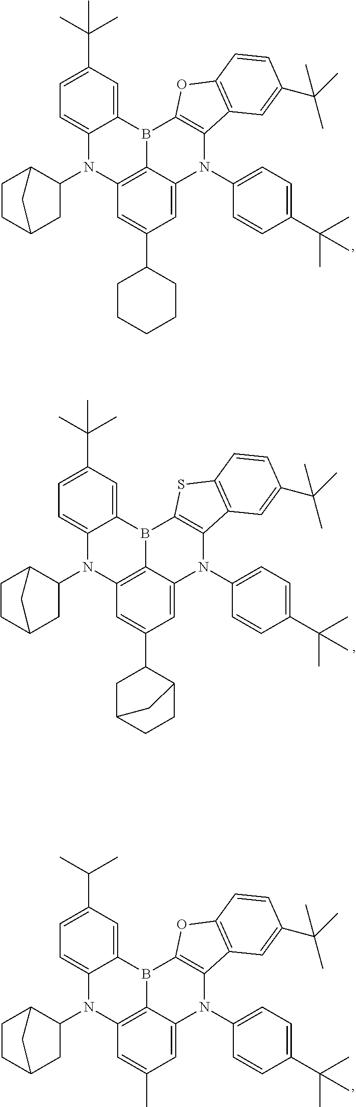 [SMILES: CC(C)(C)c1ccc(N2c3cc(C4CCCCC4)cc4c3B(c3cc(C(C)(C)C)ccc3N4C3CC4CCC3C4)c3oc4ccc(C(C)(C)C)cc4c32)cc1 ; CC(C)(C)c1ccc(N2c3cc(C4CC5CCC4C5)cc4c3B(c3cc(C(C)(C)C)ccc3N4C3CC4CCC3C4)c3sc4ccc(C(C)(C)C)cc4c32)cc1 ; Cc1cc2c3c(c1)N(C1CC4CCC1C4)c1ccc(C(C)C)cc1B3c1oc3ccc(C(C)(C)C)cc3c1N2c1ccc(C(C)(C)C)cc1]

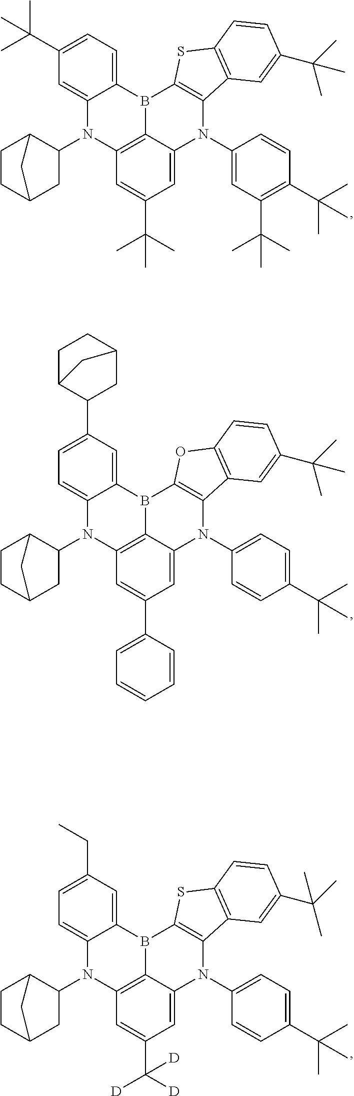 [SMILES: CC(C)(C)c1ccc2c(c1)N(C1CC3CCC1C3)c1cc(C(C)(C)C)cc3c1B2c1sc2ccc(C(C)(C)C)cc2c1N3c1ccc(C(C)(C)C)c(C(C)(C)C)c1 ; CC(C)(C)c1ccc(N2c3cc(-c4ccccc4)cc4c3B(c3cc(C5CC6CCC5C6)ccc3N4C3CC4CCC3C4)c3oc4ccc(C(C)(C)C)cc4c32)cc1 ; [2H]C([2H])([2H])c1cc2c3c(c1)N(C1CC4CCC1C4)c1ccc(CC)cc1B3c1sc3ccc(C(C)(C)C)cc3c1N2c1ccc(C(C)(C)C)cc1]

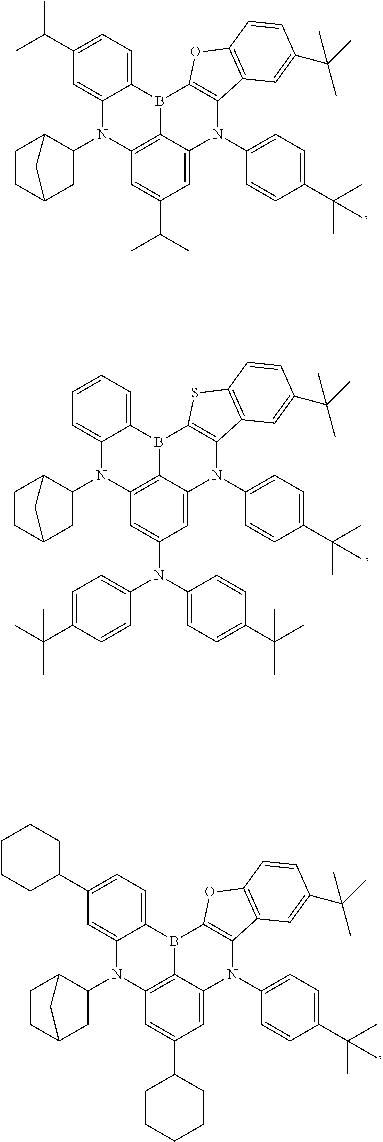 [SMILES: CC(C)c1ccc2c(c1)N(C1CC3CCC1C3)c1cc(C(C)C)cc3c1B2c1oc2ccc(C(C)(C)C)cc2c1N3c1ccc(C(C)(C)C)cc1 ; CC(C)(C)c1ccc(N(c2ccc(C(C)(C)C)cc2)c2cc3c4c(c2)N(C2CC5CCC2C5)c2ccccc2B4c2sc4ccc(C(C)(C)C)cc4c2N3c2ccc(C(C)(C)C)cc2)cc1 ; CC(C)(C)c1ccc(N2c3cc(C4CCCCC4)cc4c3B(c3ccc(C5CCCCC5)cc3N4C3CC4CCC3C4)c3oc4ccc(C(C)(C)C)cc4c32)cc1]

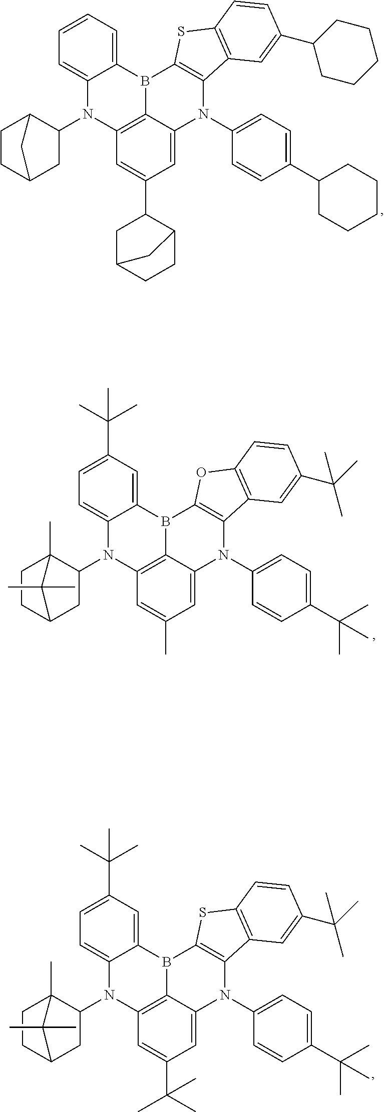

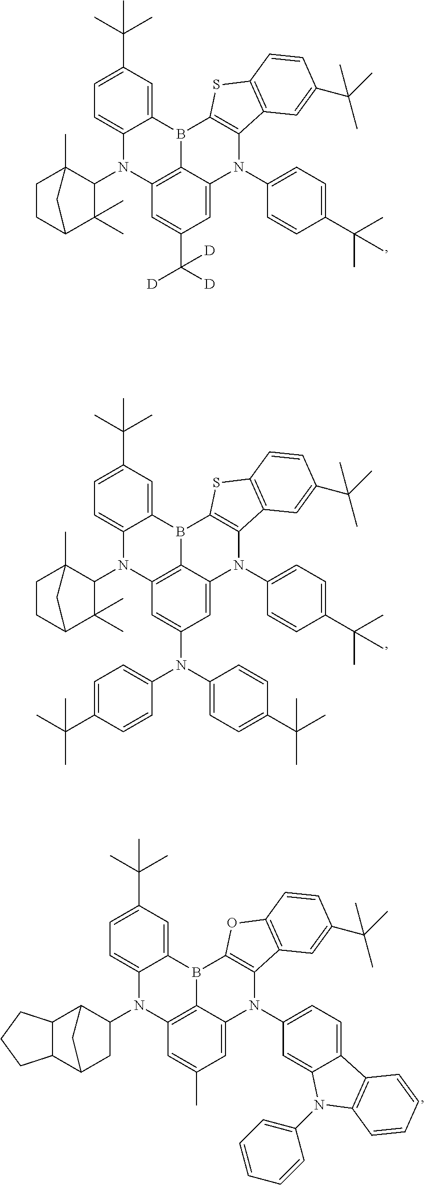 [SMILES: [2H]C([2H])([2H])c1cc2c3c(c1)N(C1C4(C)CCC(C4)C1(C)C)c1ccc(C(C)(C)C)cc1B3c1sc3ccc(C(C)(C)C)cc3c1N2c1ccc(C(C)(C)C)cc1 ; CC(C)(C)c1ccc(N(c2ccc(C(C)(C)C)cc2)c2cc3c4c(c2)N(C2C5(C)CCC(C5)C2(C)C)c2ccc(C(C)(C)C)cc2B4c2sc4ccc(C(C)(C)C)cc4c2N3c2ccc(C(C)(C)C)cc2)cc1 ; Cc1cc2c3c(c1)N(C1CC4CC1C1CCCC41)c1ccc(C(C)(C)C)cc1B3c1oc3ccc(C(C)(C)C)cc3c1N2c1ccc2c3ccccc3n(-c3ccccc3)c2c1]

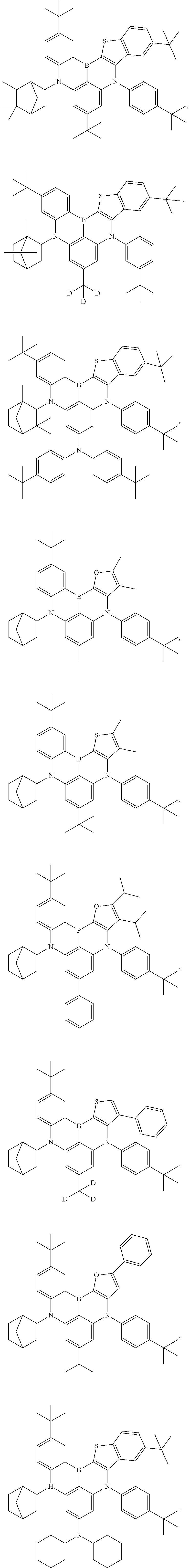

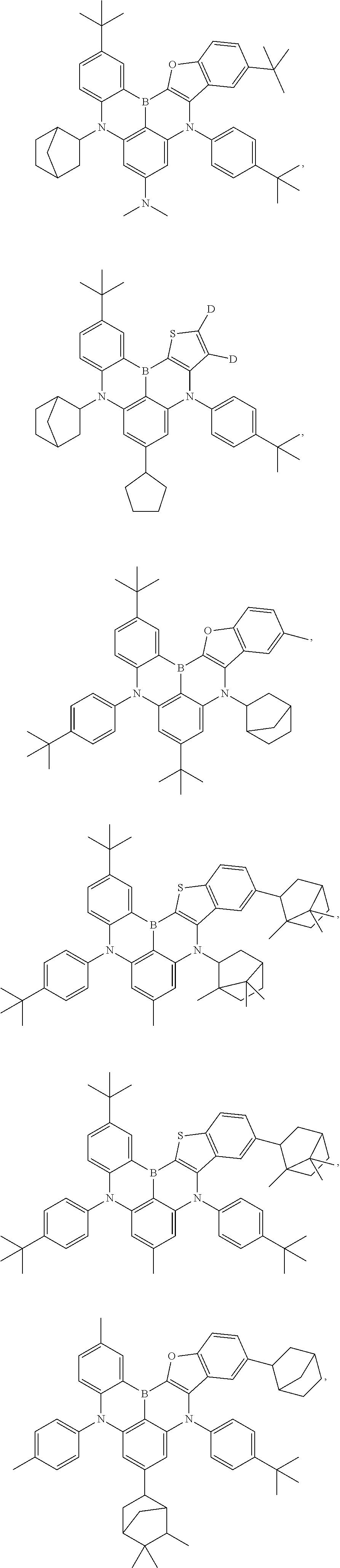

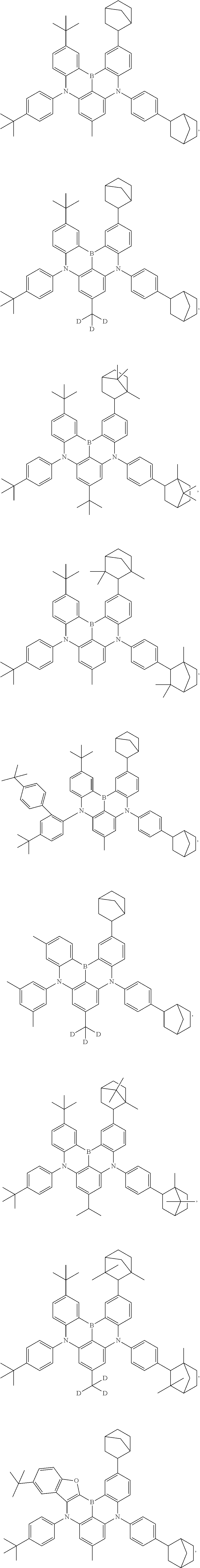

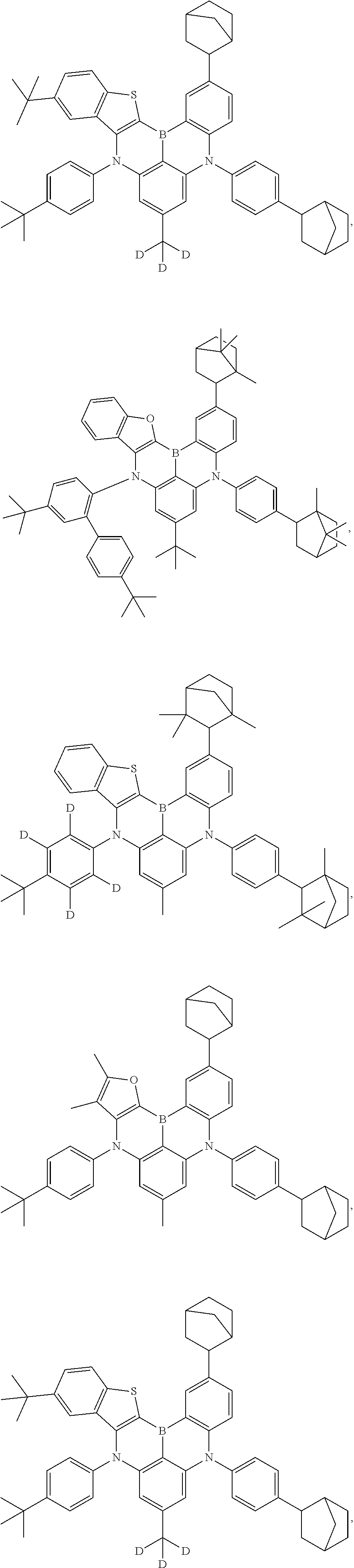

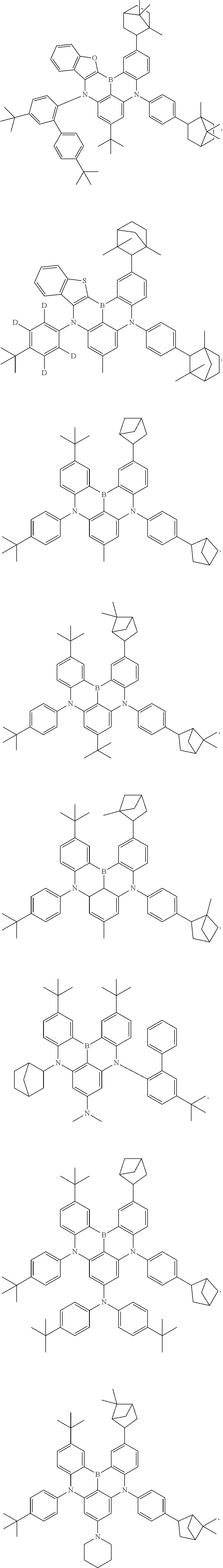

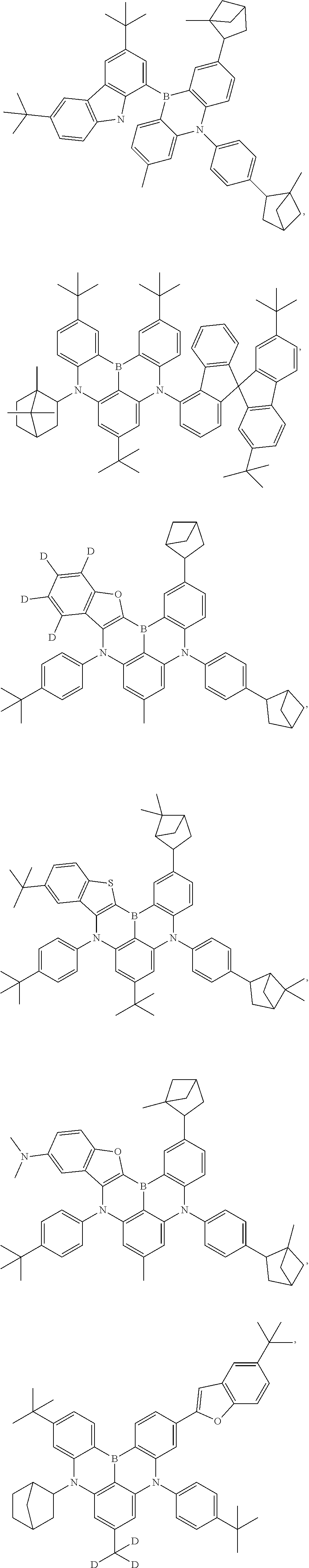

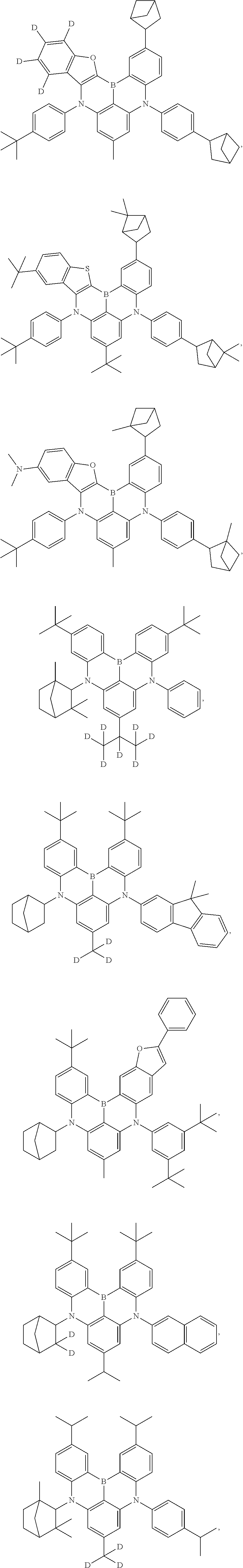

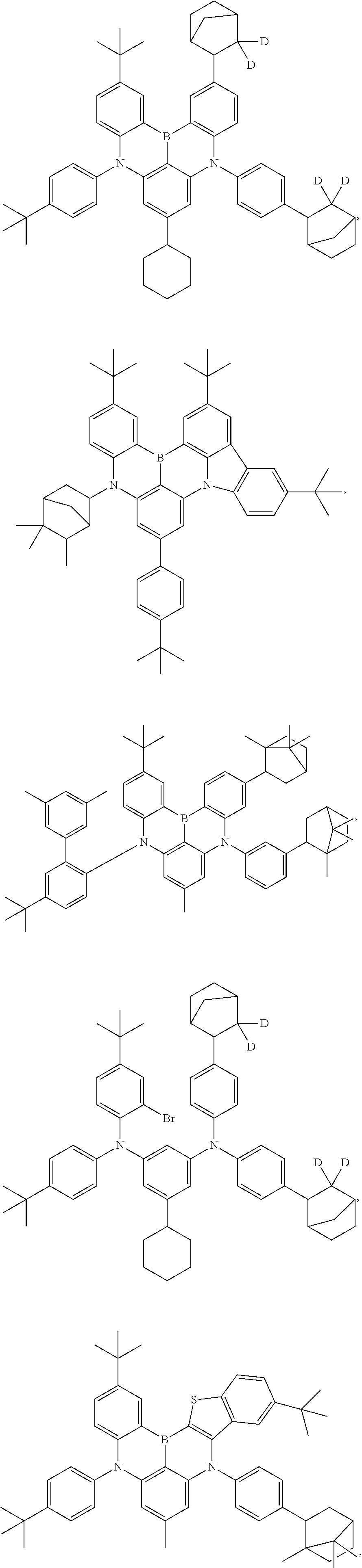

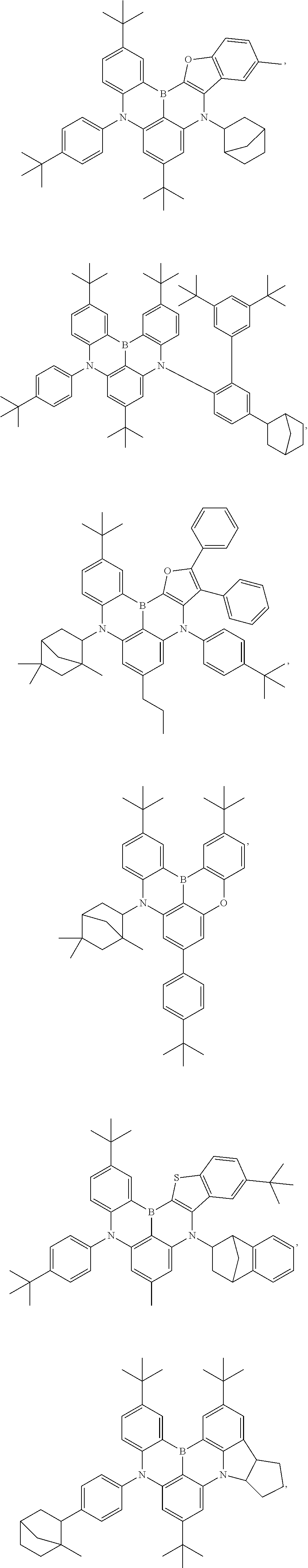

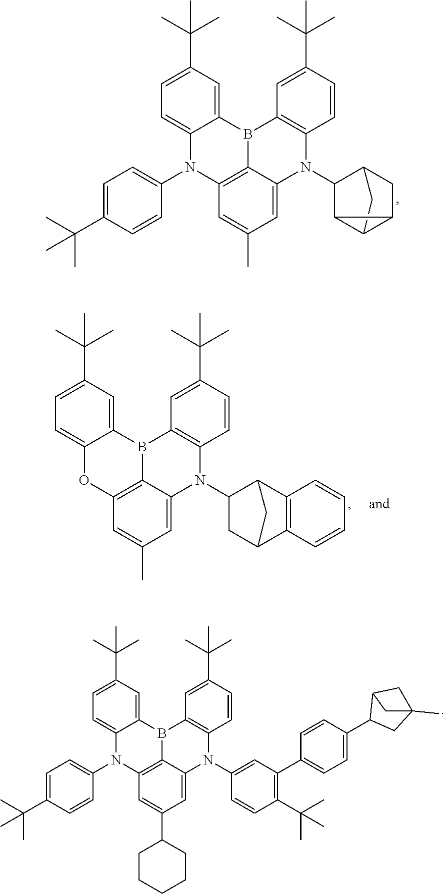 [SMILES: Cc1cc2c3c(c1)N(C1C4CC5C(C4)C51)c1ccc(C(C)(C)C)cc1B3c1cc(C(C)(C)C)ccc1N2c1ccc(C(C)(C)C)cc1 ; Cc1cc2c3c(c1)N(C1CC4CC1c1ccccc14)c1ccc(C(C)(C)C)cc1B3c1cc(C(C)(C)C)ccc1O2 ; CC12CC(C1)C(c1ccc(-c3cc(N4c5ccc(C(C)(C)C)cc5B5c6cc(C(C)(C)C)ccc6N(c6ccc(C(C)(C)C)cc6)c6cc(C7CCCCC7)cc4c65)ccc3C(C)(C)C)cc1)C2]

In a second aspect of the present invention, there is provided an organic electroluminescent device comprising an anode, a hole transport region, a luminescent layer, an electron transport region, and a cathode, which are arranged in this order on a substrate plate, wherein the luminescent layer comprises one or more of the polycyclic compounds mentioned above.

Furthermore, the luminescent layer comprises a host material and a doping material, wherein the doping material comprises one or more of the polycyclic compounds as mentioned above.

### Beneficial Effects of the Invention

The present invention provides a compound with multiple resonance characteristics. By introducing a bridged cyclic alkyl group, the rigidity of the polycyclic compound is increased, the thermal stability and glass transition temperature of a host material can be effectively improved while the dispersion of guest molecules in the material is maintained, and the lifetime of a blue-light device is significantly prolonged.

The compound provided by the present invention is suitable for blue host/dopant systems and organic electroluminescent devices of blue-series AM-OLEDs, and organic electroluminescent devices containing the compound have a higher external quantum efficiency, a lower driving voltage, and a particularly excellent lifetime.

### BRIEF DESCRIPTION OF THE DRAWINGS

FIG. 1 is a schematic structural diagram of an organic electroluminescent device containing a polycyclic compound of the present invention;

In the Brief Description of the Drawings: 1—substrate, 2—anode, 3—hole injection layer, 4—hole transport layer, 5—luminescent auxiliary layer, 6—luminescent layer, 7—electron transport layer, 8—electron injection layer, and 9—cathode.

### DETAILED DESCRIPTION OF EMBODIMENTS

In order to understand the content of the present invention more clearly, the present invention will be described in detail in conjunction with the accompanying drawings and examples.

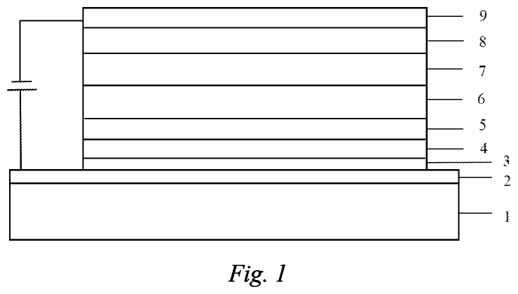

The compound of the present invention is suitable for light-emitting elements, display panels, and electronic devices, especially for organic electroluminescent devices. The electronic device described in the present invention is a device that comprises at least one layer containing at least one organic compound, and the device may also comprise an inorganic material or a layer formed entirely of an inorganic material. The electronic device is preferably an organic electroluminescent device (OLED), an organic integrated circuit (O-IC), an organic field-effect transistor (O-FET), an organic thin film transistor (O-TFT), an organic light-emitting transistor (O-LET), an organic solar cell (O-SC), an organic dye-sensitized solar cell (O-DSSC), an organic optical detector, an organic photosensor, an organic field-quenching device (O-FQD), a luminescent electrochemical cell (LEC), an organic laser diode (O-laser), and an organic plasma emitting device. The electronic device is preferably an organic electroluminescent device (OLED). The structural diagram of an exemplary organic electroluminescent device is as shown in FIG. 1.

### Experimental Part

In order to understand the content of the present invention more clearly, the compound, the preparation method for the compound, and the luminescent characteristics of the device will be explained in detail in conjunction with examples. Various chemical reactions can be applied to the synthesis method for a compound according to one embodiment of the present invention. However, it should be noted that the synthesis method for the compound according to one embodiment of the present invention is not limited to the synthesis method described below. Unless otherwise specified, the subsequent synthesis is carried out in an anhydrous solvent in a protective gas atmosphere. Solvents and reagents can be purchased from conventional reagent suppliers.

### Compound

### Synthesis of Intermediate

### Synthesis Example 1

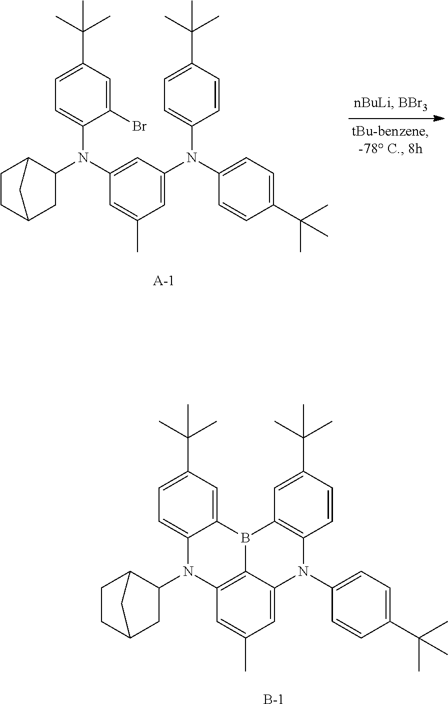

Under nitrogen protection, A-1 (13.84 g, 20 mmol) and anhydrous tert-butyl benzene (200 mL) were placed in a reaction flask and cooled to −78° C., a pentane solution of n-butyl lithium (6.5 g, 100 mmol) was slowly dropwise added to the stirred reaction system, the reaction system was slowly heated to −30° C. and stirred for 2 hours, and boron tribromide (24.92 g, 0.1 mol) was then dropwise added. Subsequently, the reaction system was heated to room temperature and stirred for 2 hours, N,N-diisopropylethylamine (25.2 g, 0.2 mol) was then added thereto, the reaction system was heated to 145° C., maintained for 4 hours, and then cooled to room temperature, and a saturated sodium bicarbonate aqueous solution was then added. After extraction with ethyl acetate, the organic phase was filtered, then dried with anhydrous sodium sulfate, and subjected to rotary evaporation to remove the solvent. The crude product was purified by column chromatography. Product B-1 was finally obtained: 1.24 g (yield: 10%), MS (m/z) (M+): 621.

### Synthesis Example 2

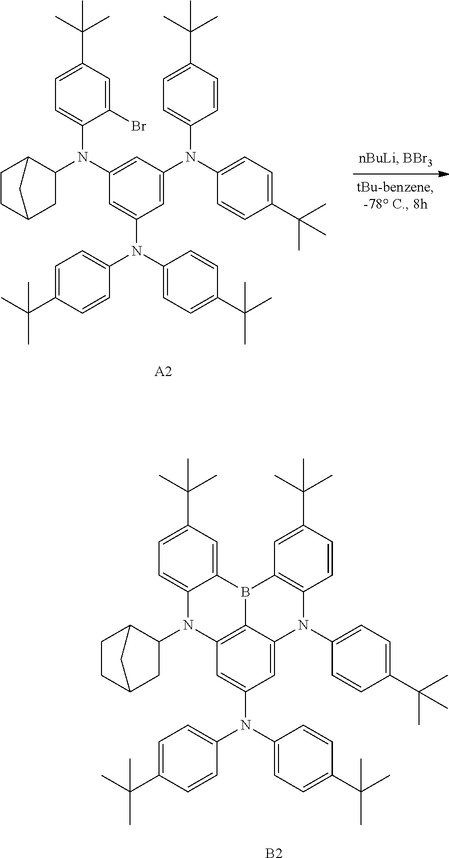 [SMILES: CC(C)(C)c1ccc(N(c2ccc(C(C)(C)C)cc2)c2cc(N(c3ccc(C(C)(C)C)cc3)c3ccc(C(C)(C)C)cc3)cc(N(c3ccc(C(C)(C)C)cc3Br)C3CC4CCC3C4)c2)cc1 ; "A2" ; CC(C)(C)c1ccc(N(c2ccc(C(C)(C)C)cc2)c2cc3c4c(c2)N(C2CC5CCC2C5)c2ccc(C(C)(C)C)cc2B4c2cc(C(C)(C)C)ccc2N3c2ccc(C(C)(C)C)cc2)cc1 ; "B2"]

This method was similar to that for the synthesis of B-1. A-2 (9.57 g, 10 mmol) was used instead of A-1 to finally obtain product B-2: 1.51 g (yield: 17%), MS (m/z) (M+): 886.

### Synthesis Example 3

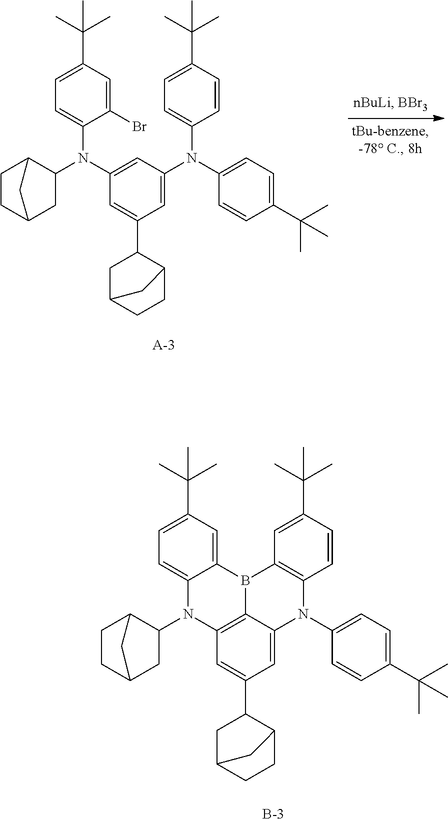

This method was similar to that for the synthesis of B-1. A-3 (7.72 g, 10 mmol) was used instead of A-1 to finally obtain product B-3: 1.40 g (yield: 20%), MS (m/z) (M+): 701.

### Synthesis Example 4

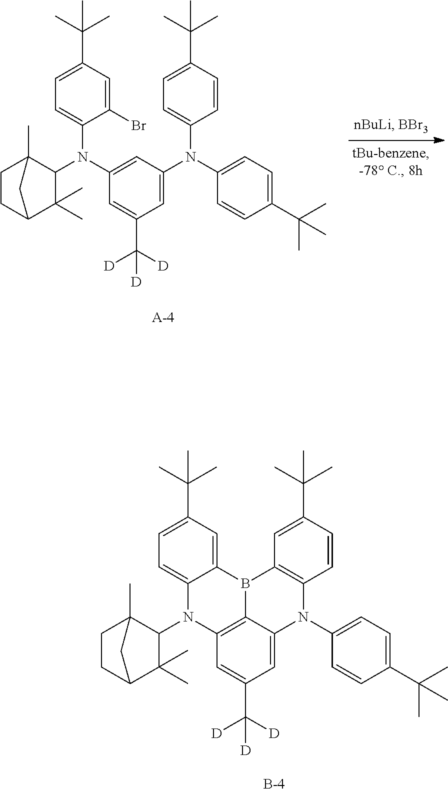

This method was similar to that for the synthesis of B-1. A-4 (7.37 g, 10 mmol) was used instead of A-1 to finally obtain product B-4: 0.67 g (yield: 10%), MS (m/z) (M+): 666.

### Synthesis Example 5

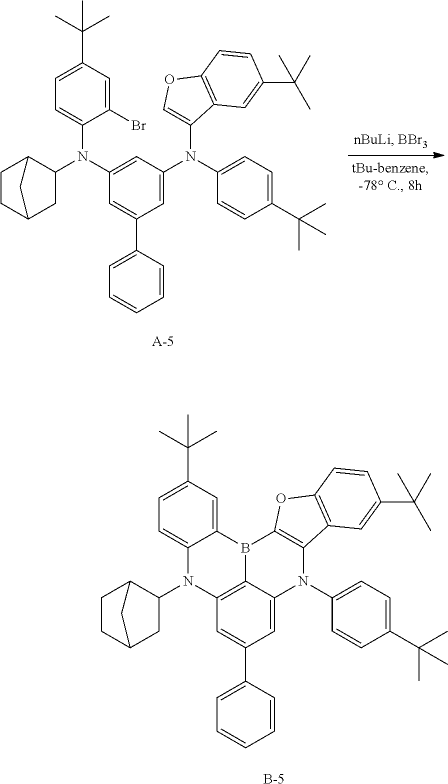

This method was similar to that for the synthesis of B-1. A-5 (7.94 g, 10 mmol) was used instead of A-1 to finally obtain product B-5: 1.08 g (yield: 15%), MS (m/z) (M+): 723.

### Synthesis Example 6

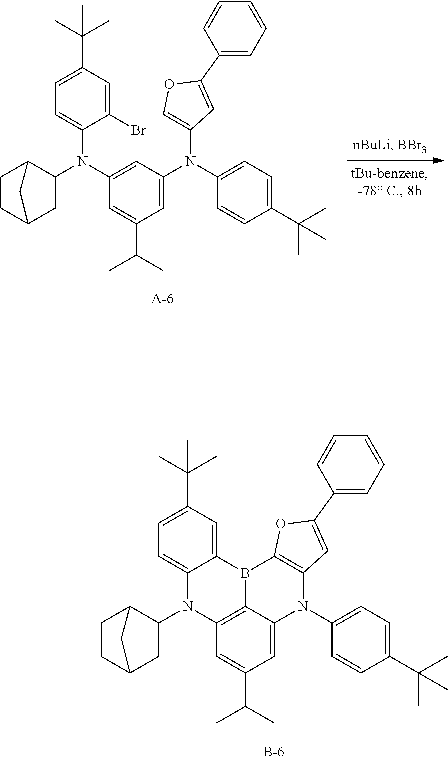

This method was similar to that for the synthesis of B-1. A-6 (7.30 g, 10 mmol) was used instead of A-1 to finally obtain product B-6: 1.19 g (yield: 18%), MS (m/z) (M+): 659.

### Synthesis Example 7

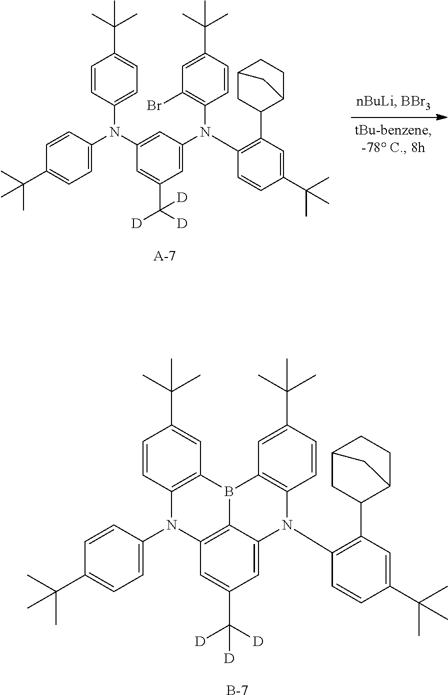

This method was similar to that for the synthesis of B-1. A-7 (8.27 g, 10 mmol) was used instead of A-1 to finally obtain product B-7: 1.67 g (yield: 22%), MS (m/z) (M+): 756.

### Synthesis Example 8

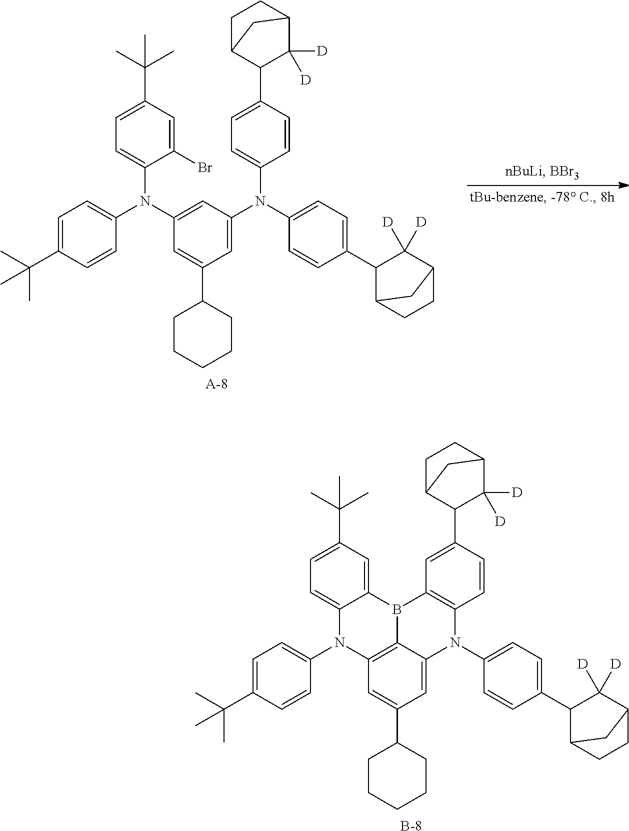

This method was similar to that for the synthesis of B-1. A-8 (8.78 g, 10 mmol) was used instead of A-1 to finally obtain product B-8: 0.95 g (yield: 11%), MS (m/z) (M+): 807.

### Synthesis Example 9

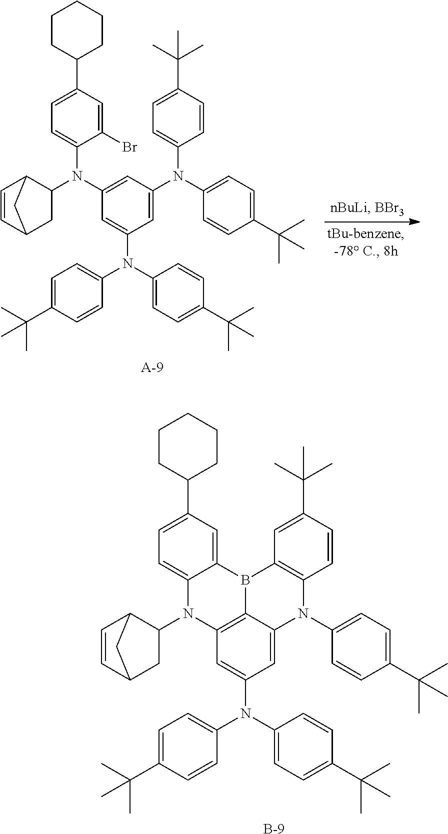

This method was similar to that for the synthesis of B-1. A-9 (9.81 g, 10 mmol) was used instead of A-1 to finally obtain product B-9: 1.64 g (yield: 18%), MS (m/z) (M+): 910.

### Synthesis Example 10

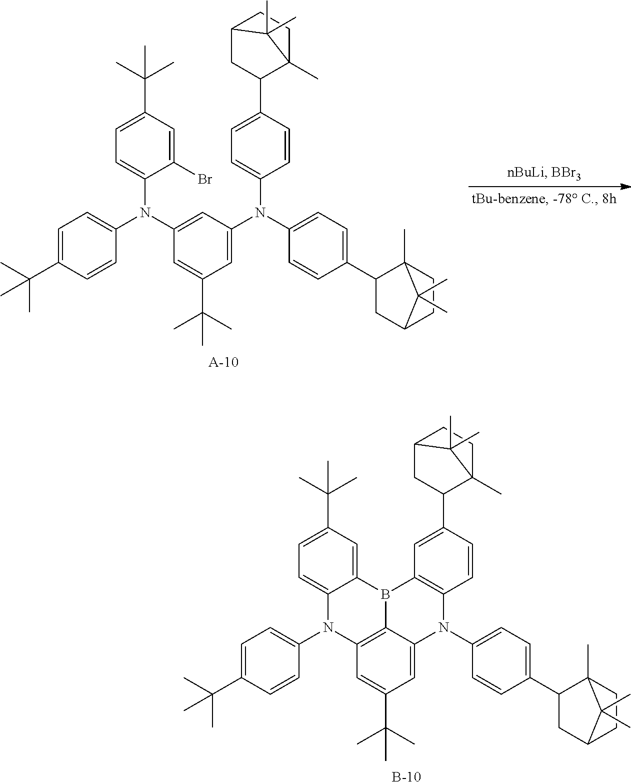

This method was similar to that for the synthesis of B-1. A-10 (9.32 g, 10 mmol) was used instead of A-1 to finally obtain product B-10: 0.95 g (yield: 11%), MS (m/z) (M+): 861.

### Synthesis Example 11

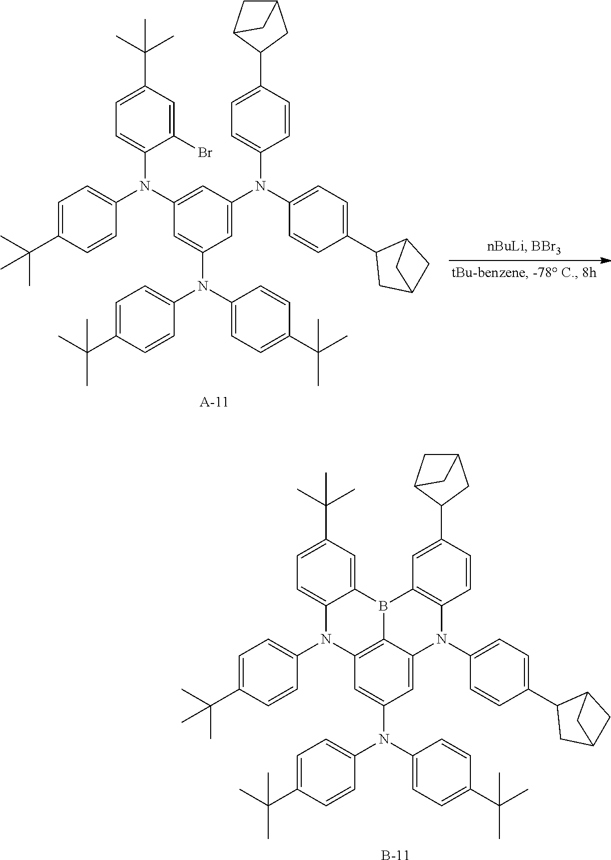

This method was similar to that for the synthesis of B-1. A-11 (10.43 g, 10 mmol) was used instead of A-1 to finally obtain product B-11: 1.56 g (yield: 16%), MS (m/z) (M+): 972.

### Synthesis Example 12

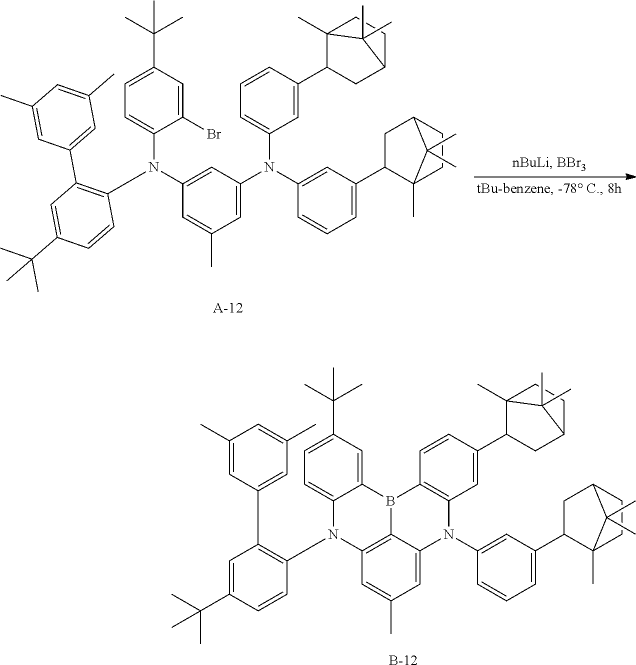

This method was similar to that for the synthesis of B-1. A-12 (9.94 g, 10 mmol) was used instead of A-1 to finally obtain product B-12: 1.36 g (yield: 14%), MS (m/z) (M+): 923.

### Synthesis Example 13

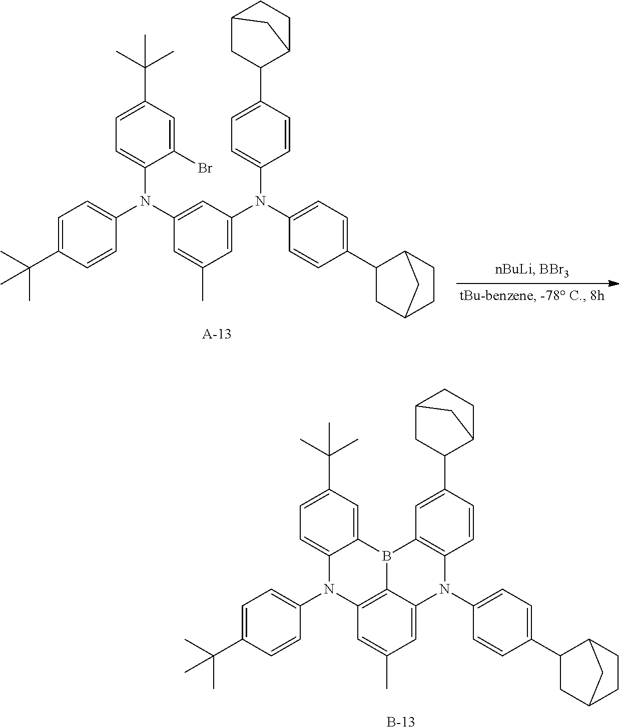

This method was similar to that for the synthesis of B-1. A-13 (8.06 g, 10 mmol) was used instead of A-1 to finally obtain product B-13: 1.10 g (yield: 15%), MS (m/z) (M+): 735.

### Synthesis Example 14

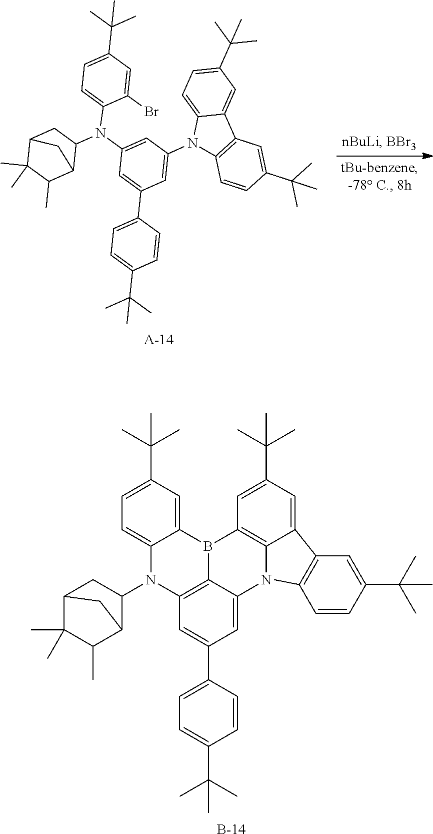

This method was similar to that for the synthesis of B-1. A-14 (8.50 g, 10 mmol) was used instead of A-1 to finally obtain product B-14: 0.93 g (yield: 12%), MS (m/z) (M+): 779.

### Synthesis Example 15

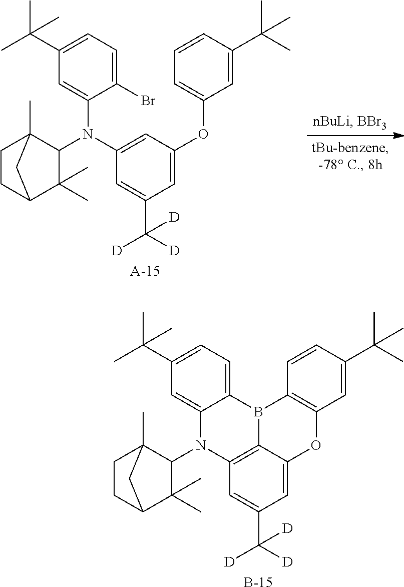

This method was similar to that for the synthesis of B-1. A-15 (6.06 g, 10 mmol) was used instead of A-1 to finally obtain product B-15: 0.59 g (yield: 11%), MS (m/z) (M+): 535.

### Synthesis Example 16

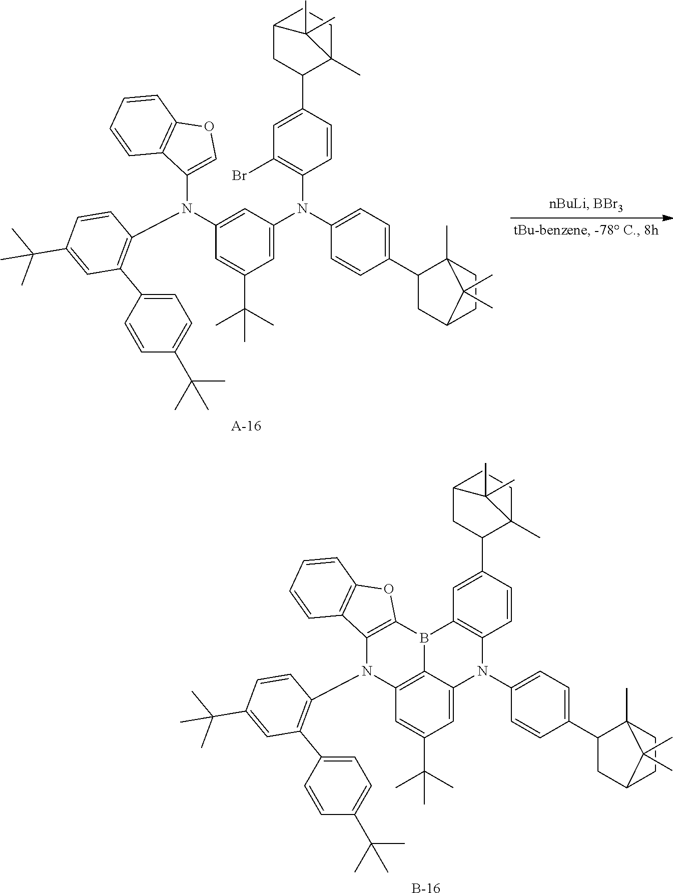

This method was similar to that for the synthesis of B-1. A-16 (10.48 g, 10 mmol) was used instead of A-1 to finally obtain product B-16: 1.76 g (yield: 18%), MS (m/z) (M+): 977.

### Synthesis Example 17

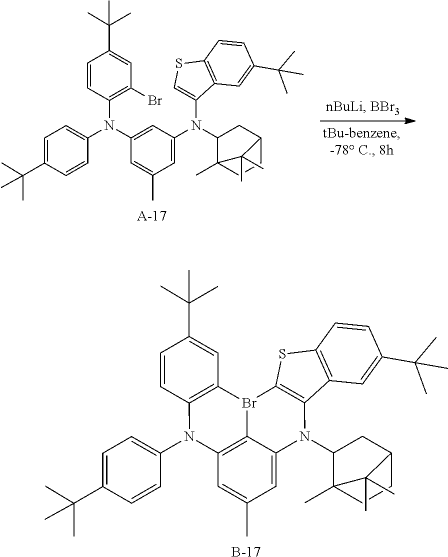

This method was similar to that for the synthesis of B-1. A-17 (7.90 g, 10 mmol) was used instead of A-1 to finally obtain product B-17: 1.37 g (yield: 19%), MS (m/z) (M+): 719.

### Synthesis Example 18

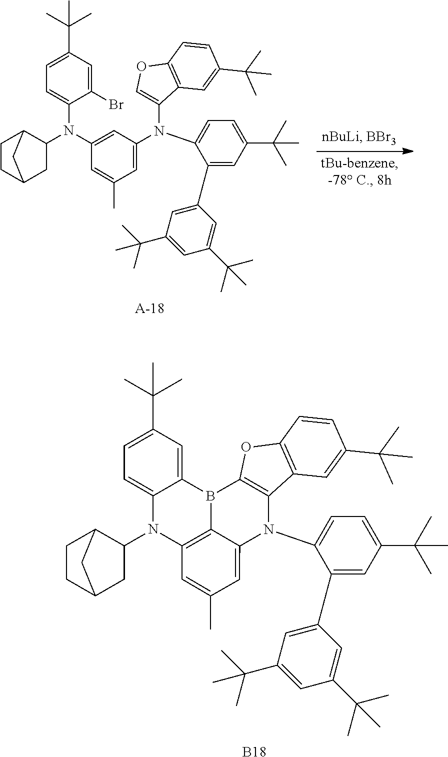

This method was similar to that for the synthesis of B-1. A-18 (9.20 g, 10 mmol) was used instead of A-1 to finally obtain product B-18: 1.53 g (yield: 18%), MS (m/z) (M+): 849.

### Evaluation of Thermal Stability

Thermal stability experiment: An appropriate amount of a sample was taken and put into a clean quartz tube. After evacuation, the mouth of the quartz tube was fused and sealed by means of an oxyhydrogen flame spray gun, and the sample was slowly heated to a sublimation temperature of +30° C. and maintained for 240 h, after which the sample was slowly cooled to room temperature, wherein the heating and cooling rates were kept to be 10° C./h or less in order to avoid the influence of sudden temperature change on the test. Subsequently, the sample was taken out and measured for purity. If the purity reduction value was less than 0.5%, it was considered passed the thermal stability evaluation.

TABLE 1
Thermal stability data of compounds of Examples 1-18

| | Purity | Evaluation |
|---|---|---|
| | reduction | of thermal |
| No. | value | stability |
| B-1 | 0.36% | Passed |
| B-2 | 0.31% | Passed |
| B-3 | 0.40% | Passed |
| B-4 | 0.14% | Passed |
| B-5 | 0.23% | Passed |
| B-6 | 0.10% | Passed |
| B-7 | 0.36% | Passed |
| B-8 | 0.21% | Passed |
| B-9 | 0.09% | Passed |
| B-10 | 0.07% | Passed |
| B-11 | 0.08% | Passed |
| B-12 | 0.34% | Passed |
| B-13 | 0.07% | Passed |
| B-14 | 0.12% | Passed |
| B-15 | 0.08% | Passed |
| B-16 | 0.33% | Passed |
| B-17 | 0.21% | Passed |
| B-18 | 0.35% | Passed |

From the data in Table 1, it could be seen that the compound containing a bridge ring as provided by the present invention had a good thermal stability, and it was speculated that the reason could lie in the aromatic amine compound provided by the present invention having a suitable molecular weight, a stronger bridge ring structure rigidity, and a better stability.

### Manufacturing and Characterization of OLEDs

### Device Examples

The organic electroluminescent device provided by the present invention comprised an anode, a hole transport region, a luminescent layer, an electron transport region, and a cathode, which were arranged in this order on a substrate plate.

Furthermore, the hole transport region comprised a hole transport layer and a luminescent auxiliary layer; and the electron transport region comprised an electron transport layer and an electron injection layer.

Furthermore, the luminescent layer was composed of a host material and a doping material, wherein the host material of the luminescent layer could be composed of one molecular material or a plurality of molecular materials.

The polycyclic compound of the present invention could be used for one or more layers of the above-mentioned organic electroluminescent devices, preferably for the doping material in the luminescent layer of the devices.

The anode in the example was an anode material commonly used in the art, such as ITO, Ag or a multilayer structure thereof. The hole injection unit was made of a hole injection material commonly used in the art and was doped with F4TCNQ, HATCN, NDP-9, etc. The hole transport unit was made of a hole transport material commonly used in the art. The luminescent unit was made of a luminescent material commonly used in the art, for example, it could be composed of a host material doped with an emitting guest material, wherein the emitting guest material could be an organic material, such as a pyrene compound, or could also be a metal complex (such as the metals Ir and Pt). The electron transport unit was made of an electron transport material commonly used in the art. The electron injection layer was made of an electron injection material commonly used in the art, such as Liq, LiF, and Yb. The cathode was made of a material commonly used in the art, such as the metals Al and Ag or metal mixtures (Ag-doped Mg, Ag-doped Ca, etc.).

The electrode preparation method and the deposition method for each functional layer in this example were both conventional methods in the art, such as vacuum thermal evaporation or ink-jet printing. No more detailed repetition would be given here, and only some process details and test methods in the preparation process were supplemented as follows:

### Device Example 1

During the preparation of a blue-light device, firstly, on an ITO layer (anode) formed on a substrate, HTL and F4TCNQ (at a mass ratio of 97:3) were deposited in vacuo to a thickness of 10 nm to form a hole injection layer; secondly, on the above hole injection layer, HTL was deposited in vacuo to a thickness of 120 nm to form a hole transport layer; thirdly, on the above hole transport layer, B prime was deposited in vacuo to a thickness of 10 nm to form a luminescent auxiliary layer; again, on the above luminescent auxiliary layer, BH as a host and B-1 as a dopant were deposited in vacuo to a thickness of 20 nm, whereby the mixture with a doping mass ratio of 98:2 was deposited in vacuo to form a luminescent layer; next, on the above luminescent layer, ET-01 and Liq (at mass ratio of 1:1) were deposited in vacuo to a thickness of 35 nm to form an electron transport layer; then, on the above electron transport layer, LiF was deposited to a thickness of 0.2 nm to form an electron injection layer; and finally, on the above electron injection layer, aluminum (Al) was deposited to a thickness of 150 nm to form a cathode, thereby preparing a blue-light organic electroluminescent device.

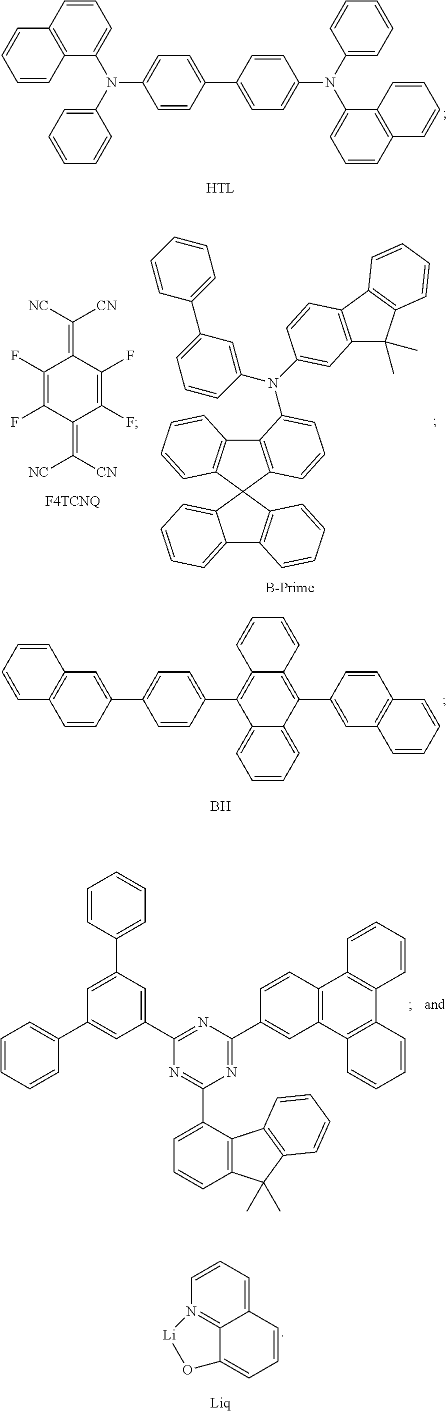

By means of the above method, the compounds described in the examples were manufactured into organic electroluminescent devices, in which B-2, B-3, B-4, B-5, B-6, B-7, B-8, B-9, B-10, B-11, B-12, B-13, B-14, B-15, B-16, B-17, and B-18 were used instead of B-1 to manufacture blue-light organic electroluminescent devices of Examples 2-18.

### Comparative Device Example

By means of the above method, Comparative Compound 1 BD was manufactured into an organic electroluminescent device as a comparative device example. In this comparative device example, BD was used instead B1 to manufacture a blue-light organic electroluminescent device as Comparative Device Example 1,

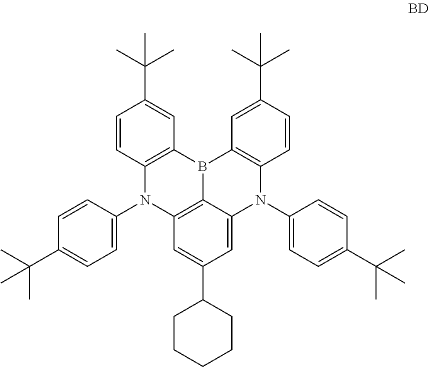 [SMILES: CC(C)(C)c1ccc(N2c3ccc(C(C)(C)C)cc3B3c4cc(C(C)(C)C)ccc4N(c4ccc(C(C)(C)C)cc4)c4cc(C5CCCCC5)cc2c43)cc1]

The OLED devices described above were tested by means of a standard method. In this regard, the organic electroluminescent devices were measured at a current density of J=10 mA/cm² for the driving voltage, brightness, electroluminescent current efficiency (measured as cd/A), and external quantum efficiency (EQE, measured by percentage). The lifetime LT was defined as the time for the brightness to decrease from the initial luminous brightness L₀ to a specific proportion L₁, during working at a constant current J; The expressions J=50 mA/cm² and L₁=90% meant that during working at 50 mA/cm², the luminous brightness decreased to 90% of the initial value L₀ thereof after the time LT. Similarly, the expressions J=20 mA/cm² and L₁=80% meant that during working at 20 mA/cm², the luminous brightness decreased to 80% of the initial value L₀ thereof after the time LT.

The data of these OLED devices were summarized in Table 1. The parameters of the examples were compared with those of the comparative examples, and the performance data of these OLED devices were exhibited.

The test instruments and methods for testing the performance of the OLED devices of the above examples and comparative examples were as follows:
the brightness was tested by means of spectrum scanner PhotoResearch PR-635;
the current density and turn-on voltage were tested by digital SourceMeter Keithley 2400; and
lifetime test: LT-96ch lifetime test device was used.

The performance test results of the above devices were listed in Table 2.

TABLE 2
Performance test results of blue-light devices

| | | | @J = 20 | |
|---|---|---|---|---|
| | | | mA/cm² | |
| No. | Vop (V) | EQE (%) | LT95 (h) | Color |
| B-1 | 3.97 | 4.77 | 48.45 | Blue |
| B-2 | 4.07 | 4.50 | 49.19 | Blue |
| B-3 | 4.01 | 4.71 | 49.24 | Blue |
| B-4 | 4.07 | 4.93 | 52.56 | Blue |
| B-5 | 3.93 | 4.96 | 49.36 | Blue |
| B-6 | 3.93 | 4.57 | 52.03 | Blue |
| B-7 | 4.06 | 4.66 | 48.17 | Blue |
| B-8 | 4.04 | 4.71 | 49.27 | Blue |
| B-9 | 3.99 | 4.58 | 50.85 | Blue |
| B-10 | 4.10 | 4.54 | 49.60 | Blue |
| B-11 | 4.00 | 4.53 | 48.09 | Blue |
| B-12 | 3.98 | 4.79 | 48.45 | Blue |
| B-13 | 3.99 | 4.60 | 48.16 | Blue |
| B-14 | 3.94 | 4.77 | 50.51 | Blue |
| B-15 | 3.91 | 4.78 | 51.23 | Blue |
| B-16 | 4.08 | 4.59 | 52.18 | Blue |
| B-17 | 4.07 | 4.82 | 52.41 | Blue |
| B-18 | 4.01 | 4.99 | 52.55 | Blue |
| Comparative | 4.20 | 4.47 | 37.21 | Blue |
| Example 1 | | | | |

From the device performance test results in Table 2 above, it could be seen that the organic electroluminescent devices manufactured from the compounds with multiple resonance characteristics of the present invention were significantly improved in terms of Vop and lifetime as compared with Comparative Device Example 1. Compared with the comparative device, the time for the luminous brightness of the devices of the above examples to decrease to 95% of the initial value L₀ thereof during working at 20 mA/cm² was significantly longer. This was because the bridge ring had a certain extent of rigidity, few unsaturated bonds, and good thermal stability. Therefore, the organic electroluminescent device manufactured by using the organic compound of the present invention had a longer lifetime. Therefore, it could be proved that the organic compounds claimed by the present invention were well-performed blue-light doping materials and have practical value.

The above description is only preferred embodiments of the present invention, and the scope of protection of the present invention is not limited thereto. Any changes, substitutions, etc. readily conceivable to any of those familiar with the technical field within the technical scope of the disclosure of the present invention should be included in the scope of protection of the present invention. Therefore, for the scope of protection of the present invention, the scope of protection of the claims shall prevail.

1. A compound with multiple resonance characteristics, characterized in that the compound has a general structural formula as represented by Formula I: 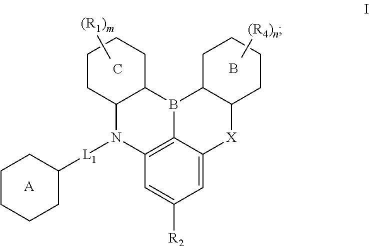
wherein ring A represents a substituted or unsubstituted bridged cyclic alkyl group with a carbon atom number of C4-C30 or a substituted or unsubstituted bridged cyclic alkenyl group with a carbon atom number of C4-C30; ring B and ring C each independently represent one of a substituted or unsubstituted aryl group with a carbon atom number of C6-C60, a substituted or unsubstituted heteroaryl group with a carbon atom number of C4-C60, a substituted or unsubstituted fused cycloaryl group with a carbon atom number of C6-C60, and a substituted or unsubstituted fused heterocycloaryl group with a carbon atom number of C5-C60;
X represents N-L2-R3 or O;
L1 and L2 each independently represent a single bond or a substituted or unsubstituted aryl group with a carbon atom number of C6-C20;
R1 and R4 each independently represent one of hydrogen, deuterium, halogen, a substituted or unsubstituted alkyl group with a carbon atom number of C1-C30, a substituted or unsubstituted alkoxy group with a carbon atom number of C1-C30, a substituted or unsubstituted alkenyl group with a carbon atom number of C2-C30, a substituted or unsubstituted cycloalkyl group with a carbon atom number of C3-C30, a substituted or unsubstituted bridged cyclic alkyl group with a carbon atom number of C4-C30, a substituted or unsubstituted aryl group with a carbon atom number of C6-C60, a substituted or unsubstituted heteroaryl group with a carbon atom number of C6-C60, a substituted or unsubstituted fused cycloaryl group with a carbon atom number of C6-C60, a substituted or unsubstituted fused heterocycloaryl group with a carbon atom number of C5-C60, and a substituted or unsubstituted arylamino group with a carbon atom number of C6-C60;
m and n each independently represent 1, 2, 3, or 4; when m and n are 2, 3, or 4, R1 and R4 can be the same or different;
R2 represents one of hydrogen, deuterium, halogen, a substituted or unsubstituted alkyl group with a carbon atom number of C1-C30, a substituted or unsubstituted cycloalkyl group with a carbon atom number of C3-C30, a substituted or unsubstituted bridged cyclic alkyl group with a carbon atom number of C4-C30, a substituted or unsubstituted bridged cyclic alkenyl group with a carbon atom number of C4-C30, a substituted or unsubstituted aryl group with a carbon atom number of C6-C60, a substituted or unsubstituted heteroaryl group with a carbon atom number of C6-C60, a substituted or unsubstituted fused cycloaryl group with a carbon atom number of C6-C60, a substituted or unsubstituted fused heterocycloaryl group with a carbon atom number of C5-C60, and a substituted or unsubstituted amino group;
R3 represents one of hydrogen, deuterium, halogen, a substituted or unsubstituted alkyl group with a carbon atom number of C1-C30, a substituted or unsubstituted alkenyl group with a carbon atom number of C2-C30, a substituted or unsubstituted cycloalkyl group with a carbon atom number of C3-C30, a substituted or unsubstituted bridged cyclic alkyl group with a carbon atom number of C4-C30, a substituted or unsubstituted aryl group with a carbon atom number of C6-C60, a substituted or unsubstituted heteroaryl group with a carbon atom number of C6-C60, a substituted or unsubstituted fused cycloaryl group with a carbon atom number of C6-C60, and a substituted or unsubstituted fused heterocycloaryl group with a carbon atom number of C5-C60; R3 can be connected to ring B to form a ring;
substituents in ring A, ring B, ring C, R1, R2, R3, R4, L1, and L2 may be the same or different and are each independently selected from one of deuterium, halogen, cyano, an alkyl group with a carbon atom number of C1-C10, an aryl group with a carbon atom number of C6-C60, a fused cycloaryl group with a carbon atom number of C6-C60, and a cycloalkyl group with a carbon atom number of C3-C30, wherein two or more substituents can be connected to each other to form an aliphatic ring, an aromatic ring, or a condensed ring; and
each hydrogen on the compound represented by Formula I can be independently replaced by deuterium.

2. The compound according to claim 1, characterized in that the amino group is selected from one of a substituted or unsubstituted alkylamino group with a carbon atom number of C1-C10, a substituted or unsubstituted arylamino group with a carbon atom number of C6-C20, a substituted or unsubstituted aralkylamino group with a carbon atom number of C6-C20, and a substituted or unsubstituted heteroarylamino group with a carbon atom number of C2-C24;
preferably, the ring formed by connecting R3 to ring B is selected from a substituted or unsubstituted aliphatic ring group, a substituted or unsubstituted aromatic ring, a substituted or unsubstituted heteroaromatic ring, and a substituted or unsubstituted condensed ring.

3. The compound according to claim 1, characterized in that the compound of Formula I is selected from one of the following structures represented by Formulas I-1 to I-6: 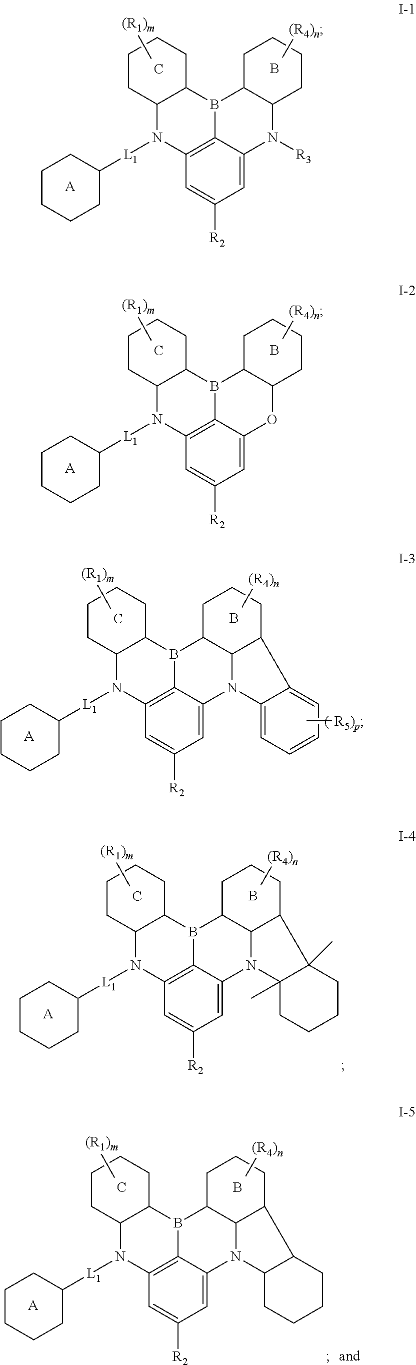 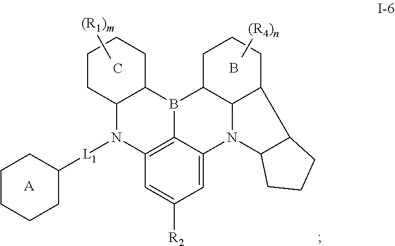
wherein R₅ represents a substituted or unsubstituted alkyl group with a carbon atom number of C₁-C₃₀, p represents 0, 1, 2, 3, or 4; and when p represents 2, 3, or 4, p can be the same or different.

4. The compound according to claim 1, characterized in that ring A represents 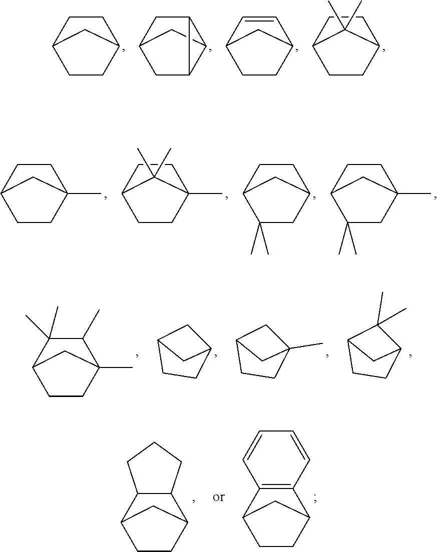
preferably, ring B and ring C each independently represent 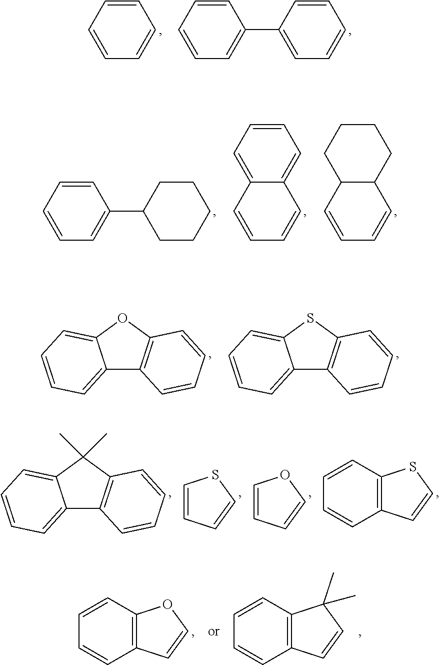
wherein any nonadjacent C in each of the above structures can be each independently replaced by N, and any hydrogen can be each independently replaced by fluorine, deuterium, cyano, linear alkyl, branched alkyl, cycloalkyl, aryl, heteroaryl, or arylamino.

5. The compound according to claim 1, characterized in that R1 and R4 each independently represent a substituted or unsubstituted linear alkyl or branched alkyl group with a carbon atom number of C1-C10,

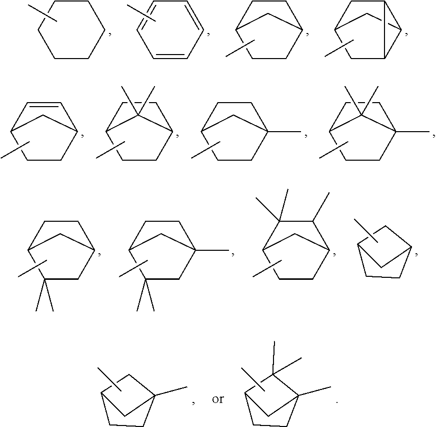

6. The compound according to claim 1, characterized in that R2 represents a substituted or unsubstituted linear alkyl or branched alkyl group with a carbon atom number of C1-C10, 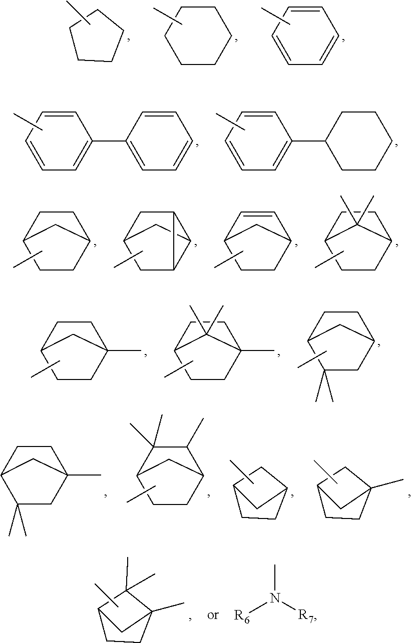
wherein R6 and R7 each independently represent a substituted or unsubstituted alkyl group with a carbon atom number of C1-C10, a substituted or unsubstituted cycloalkyl group with a carbon atom number of C3-C15, and a substituted or unsubstituted aryl group with a carbon atom number of C6-C20.

7. The compound according to claim 1, characterized in that R3 represents a substituted or unsubstituted linear alkyl or branched alkyl group with a carbon atom number of C1-C10, a substituted or unsubstituted alkenyl group with a carbon atom number of C2-C10, 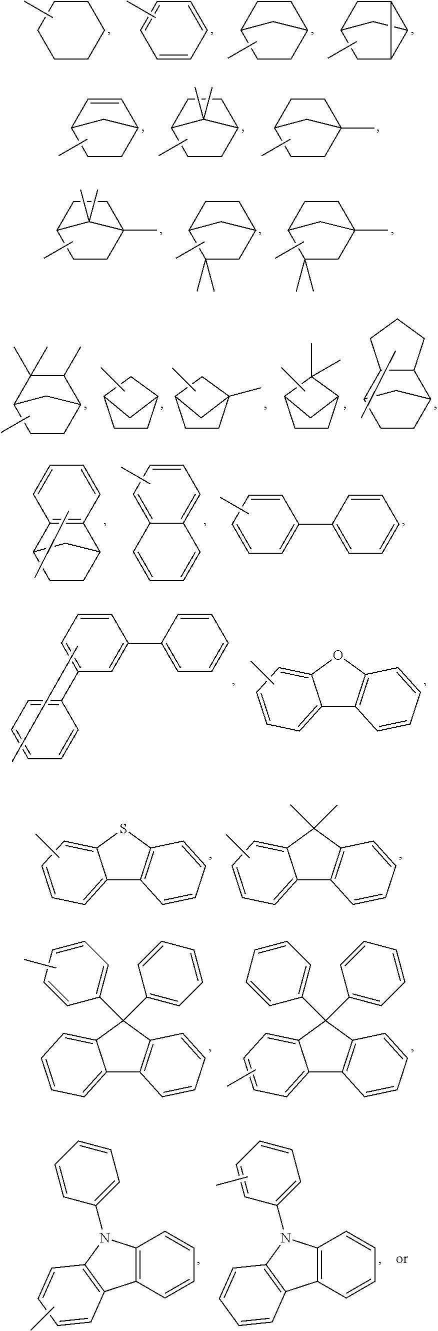 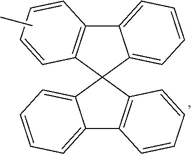
wherein any hydrogen in each of the above structures can be each independently replaced by fluorine, deuterium, linear alkyl, branched alkyl, cycloalkyl, or phenyl.

8. The compound according to claim 1, characterized in that the compound represented by Formula I is selected from any one of the following compounds:

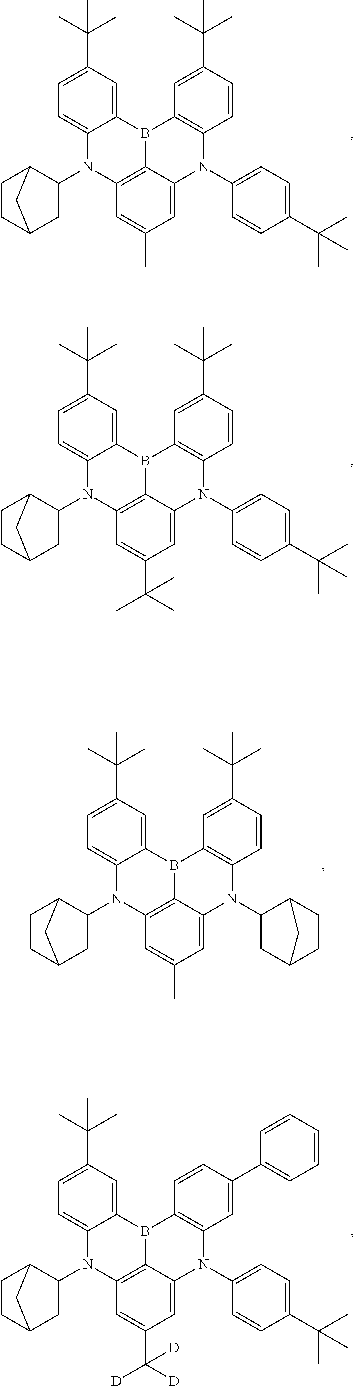 [SMILES: Cc1cc2c3c(c1)N(C1CC4CCC1C4)c1ccc(C(C)(C)C)cc1B3c1cc(C(C)(C)C)ccc1N2c1ccc(C(C)(C)C)cc1 ; CC(C)(C)c1ccc(N2c3ccc(C(C)(C)C)cc3B3c4cc(C(C)(C)C)ccc4N(C4CC5CCC4C5)c4cc(C(C)(C)C)cc2c43)cc1 ; Cc1cc2c3c(c1)N(C1CC4CCC1C4)c1ccc(C(C)(C)C)cc1B3c1cc(C(C)(C)C)ccc1N2C1CC2CCC1C2 ; [2H]C([2H])([2H])c1cc2c3c(c1)N(C1CC4CCC1C4)c1ccc(C(C)(C)C)cc1B3c1ccc(-c3ccccc3)cc1N2c1ccc(C(C)(C)C)cc1]

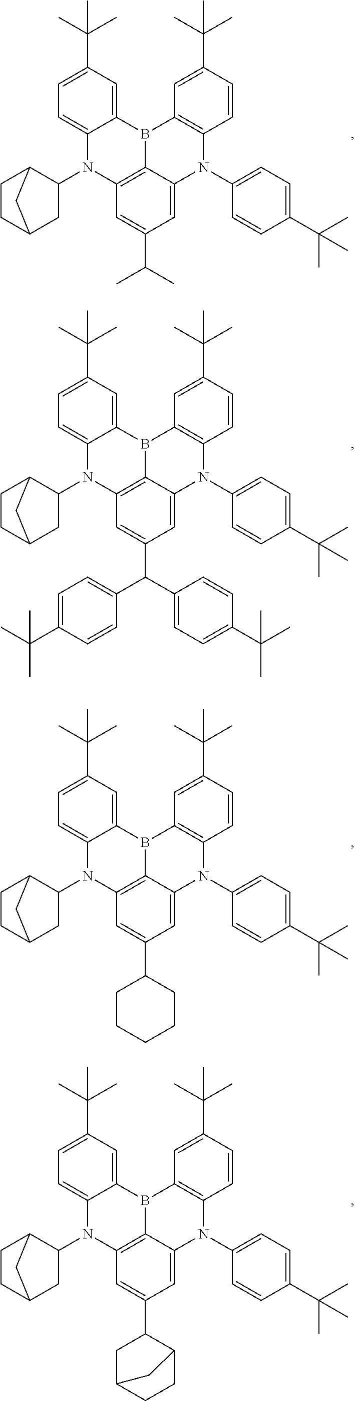

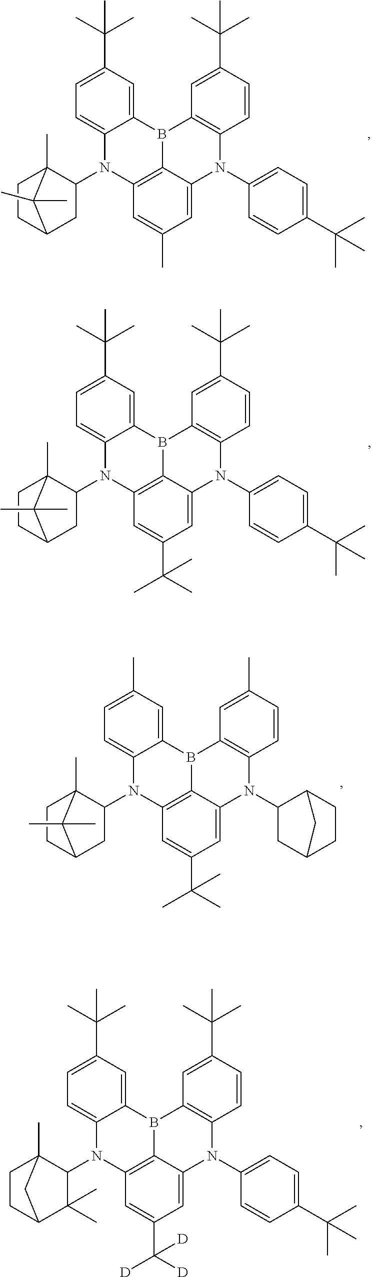

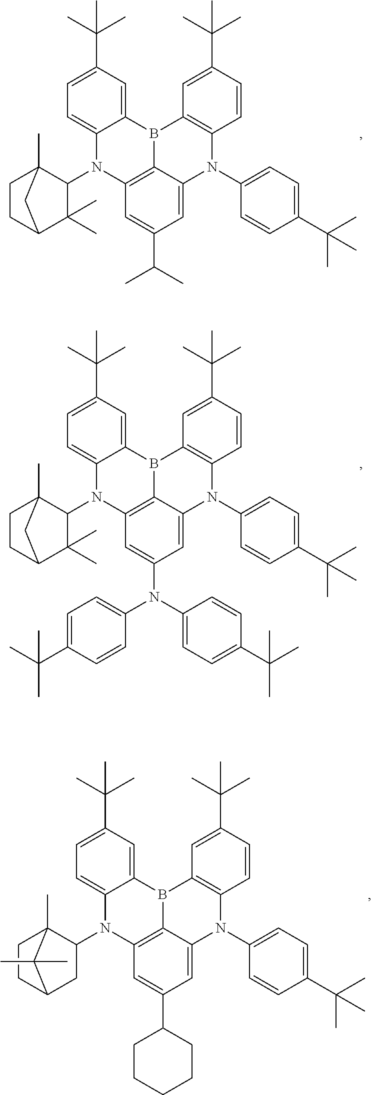

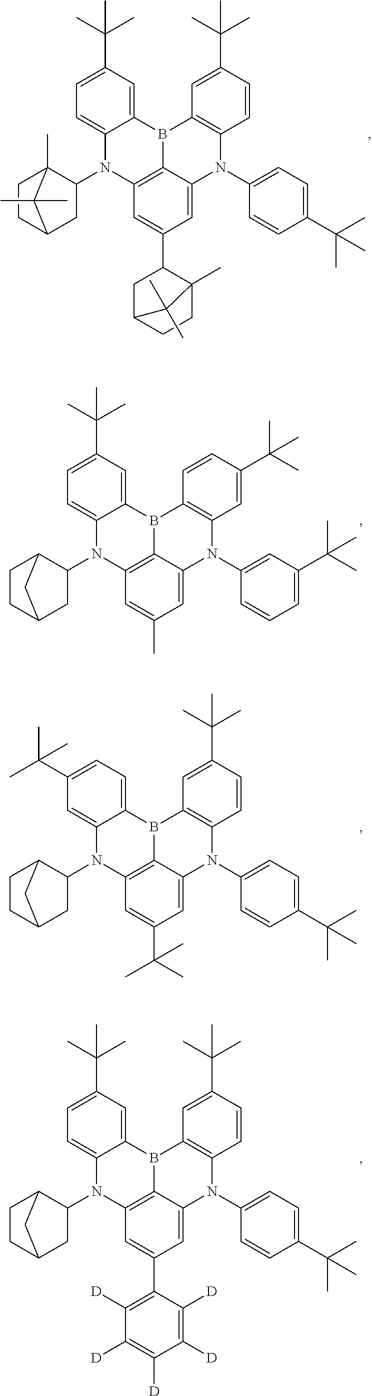 [SMILES: CC(C)(C)c1ccc(N2c3ccc(C(C)(C)C)cc3B3c4cc(C(C)(C)C)ccc4N(C4CC5CCC4(C)C5(C)C)c4cc(C5CC6CCC5(C)C6(C)C)cc2c43)cc1 ; Cc1cc2c3c(c1)N(C1CC4CCC1C4)c1ccc(C(C)(C)C)cc1B3c1ccc(C(C)(C)C)cc1N2c1cccc(C(C)(C)C)c1 ; CC(C)(C)c1ccc(N2c3ccc(C(C)(C)C)cc3B3c4ccc(C(C)(C)C)cc4N(C4CC5CCC4C5)c4cc(C(C)(C)C)cc2c43)cc1 ; [2H]c1c([2H])c([2H])c(-c2cc3c4c(c2)N(C2CC5CCC2C5)c2ccc(C(C)(C)C)cc2B4c2cc(C(C)(C)C)ccc2N3c2ccc(C(C)(C)C)cc2)c([2H])c1[2H]]

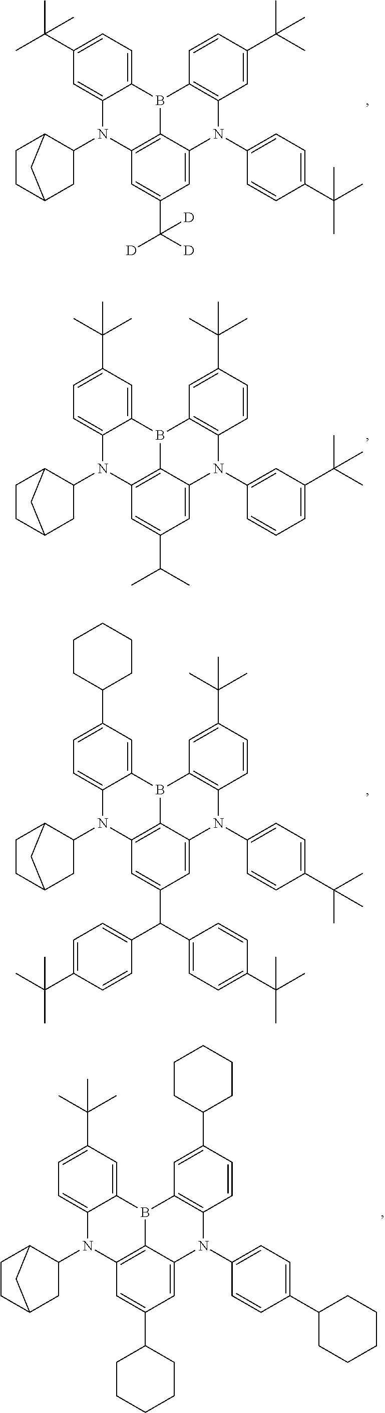 [SMILES: [2H]C([2H])([2H])c1cc2c3c(c1)N(C1CC4CCC1C4)c1cc(C(C)(C)C)ccc1B3c1ccc(C(C)(C)C)cc1N2c1ccc(C(C)(C)C)cc1 ; CC(C)c1cc2c3c(c1)N(C1CC4CCC1C4)c1ccc(C(C)(C)C)cc1B3c1cc(C(C)(C)C)ccc1N2c1cccc(C(C)(C)C)c1 ; CC(C)(C)c1ccc(C(c2ccc(C(C)(C)C)cc2)c2cc3c4c(c2)N(C2CC5CCC2C5)c2ccc(C5CCCCC5)cc2B4c2cc(C(C)(C)C)ccc2N3c2ccc(C(C)(C)C)cc2)cc1 ; CC(C)(C)c1ccc2c(c1)B1c3cc(C4CCCCC4)ccc3N(c3ccc(C4CCCCC4)cc3)c3cc(C4CCCCC4)cc(c31)N2C1CC2CCC1C2]

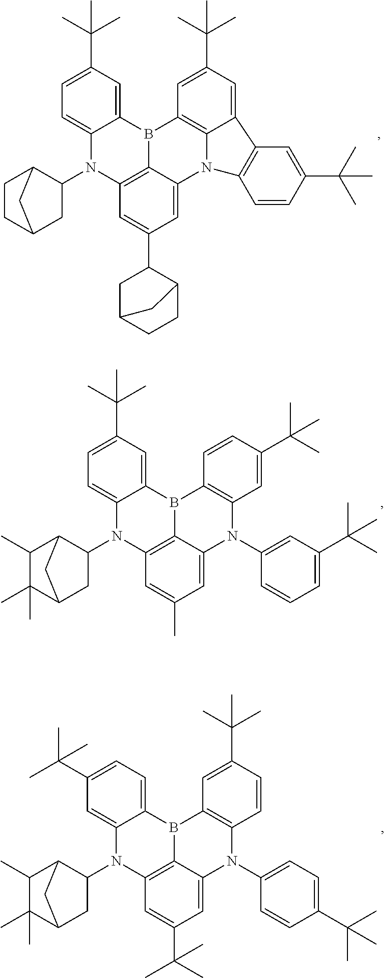

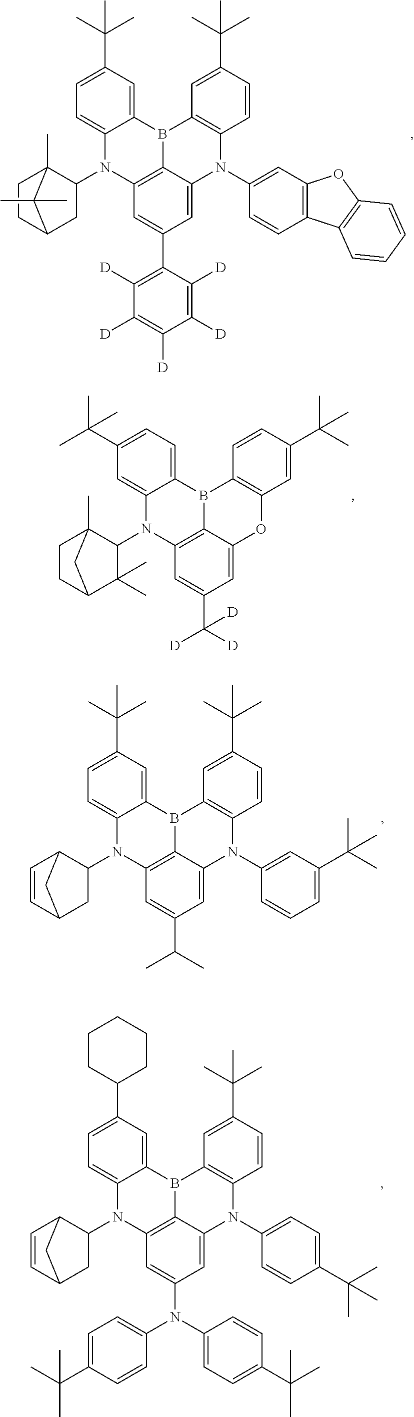

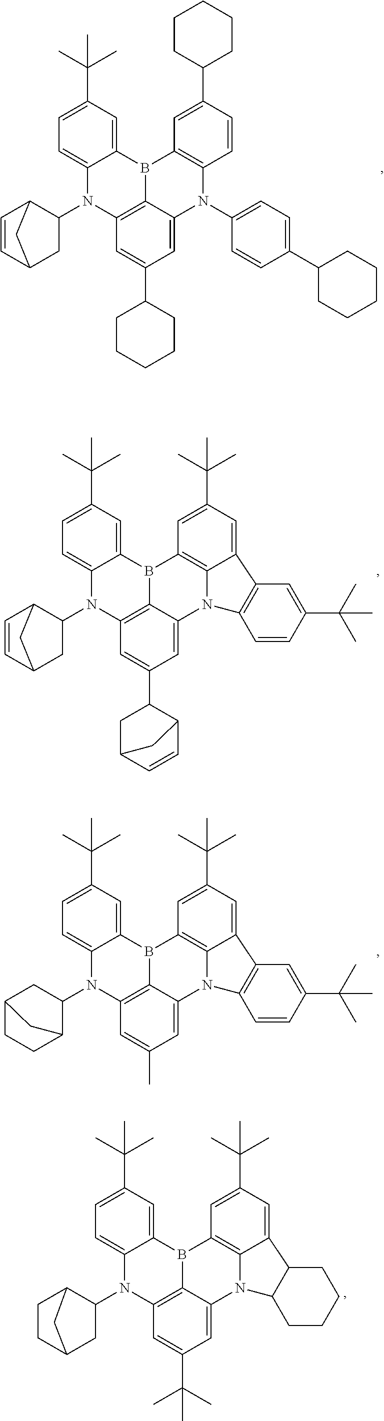

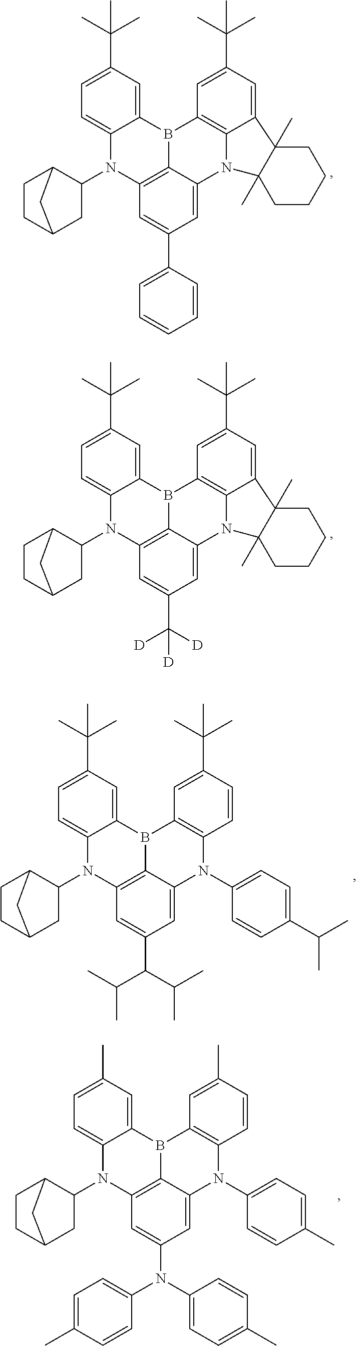

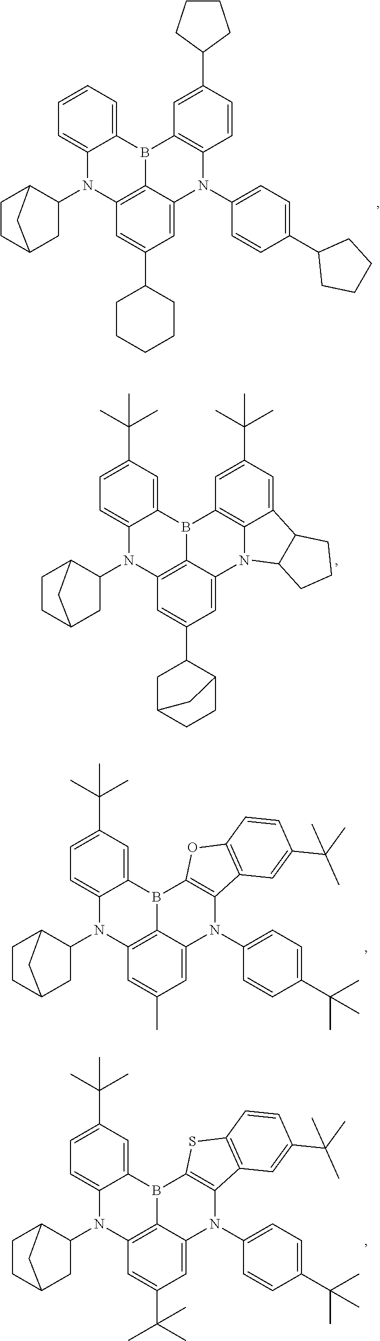

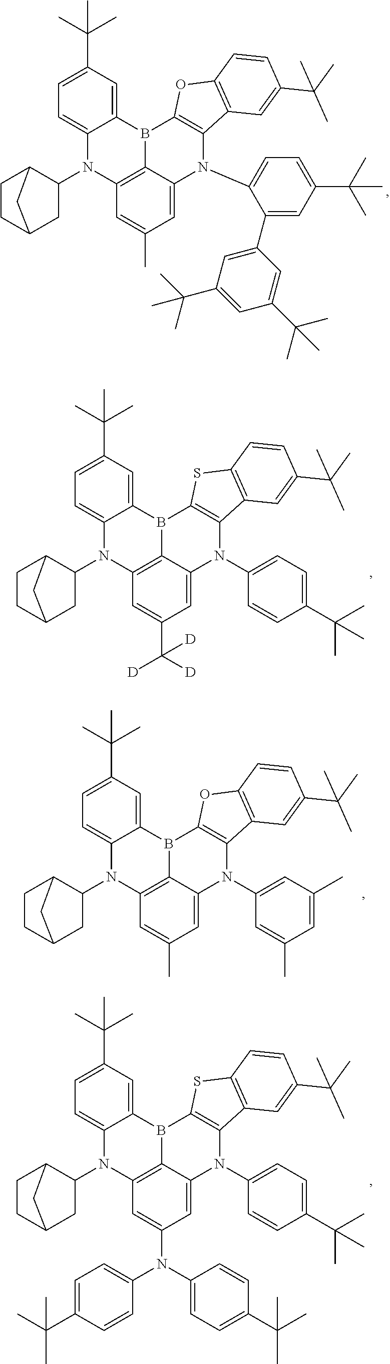

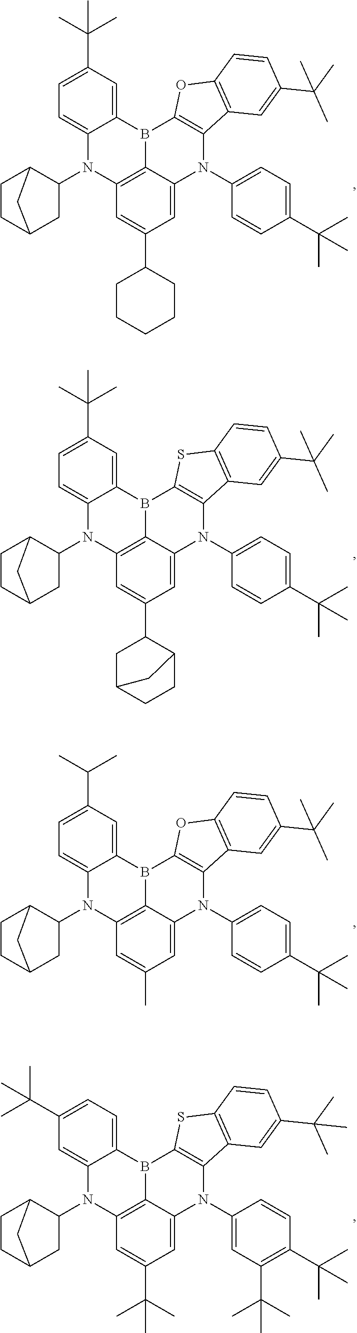 [SMILES: CC(C)(C)c1ccc(N2c3cc(C4CCCCC4)cc4c3B(c3cc(C(C)(C)C)ccc3N4C3CC4CCC3C4)c3oc4ccc(C(C)(C)C)cc4c32)cc1 ; CC(C)(C)c1ccc(N2c3cc(C4CC5CCC4C5)cc4c3B(c3cc(C(C)(C)C)ccc3N4C3CC4CCC3C4)c3sc4ccc(C(C)(C)C)cc4c32)cc1 ; Cc1cc2c3c(c1)N(C1CC4CCC1C4)c1ccc(C(C)C)cc1B3c1oc3ccc(C(C)(C)C)cc3c1N2c1ccc(C(C)(C)C)cc1 ; CC(C)(C)c1ccc2c(c1)N(C1CC3CCC1C3)c1cc(C(C)(C)C)cc3c1B2c1sc2ccc(C(C)(C)C)cc2c1N3c1ccc(C(C)(C)C)c(C(C)(C)C)c1]

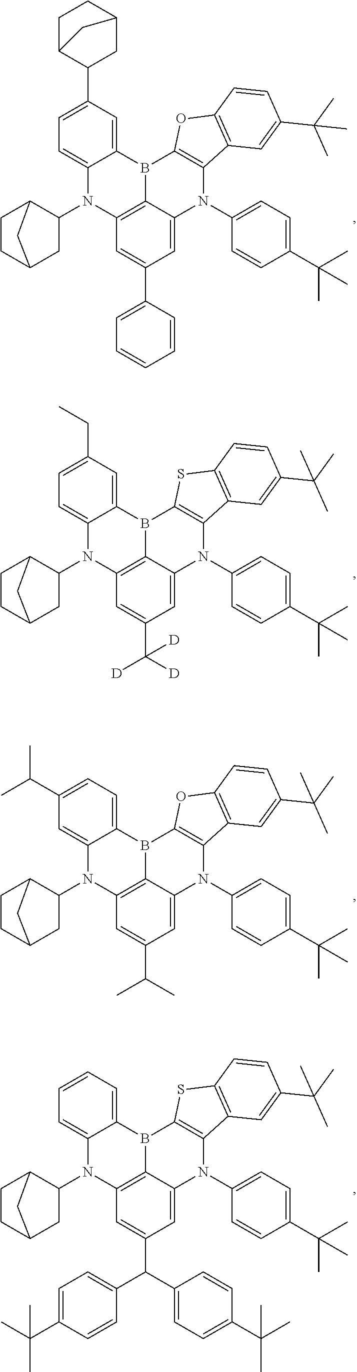 [SMILES: CC(C)(C)c1ccc(N2c3cc(-c4ccccc4)cc4c3B(c3cc(C5CC6CCC5C6)ccc3N4C3CC4CCC3C4)c3oc4ccc(C(C)(C)C)cc4c32)cc1 ; [2H]C([2H])([2H])c1cc2c3c(c1)N(C1CC4CCC1C4)c1ccc(CC)cc1B3c1sc3ccc(C(C)(C)C)cc3c1N2c1ccc(C(C)(C)C)cc1 ; CC(C)c1ccc2c(c1)N(C1CC3CCC1C3)c1cc(C(C)C)cc3c1B2c1oc2ccc(C(C)(C)C)cc2c1N3c1ccc(C(C)(C)C)cc1 ; CC(C)(C)c1ccc(C(c2ccc(C(C)(C)C)cc2)c2cc3c4c(c2)N(C2CC5CCC2C5)c2ccccc2B4c2sc4ccc(C(C)(C)C)cc4c2N3c2ccc(C(C)(C)C)cc2)cc1]

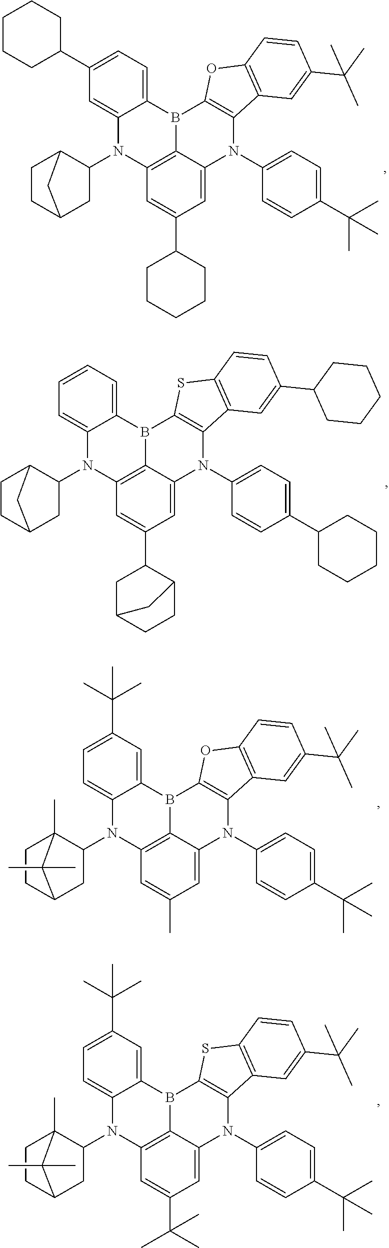

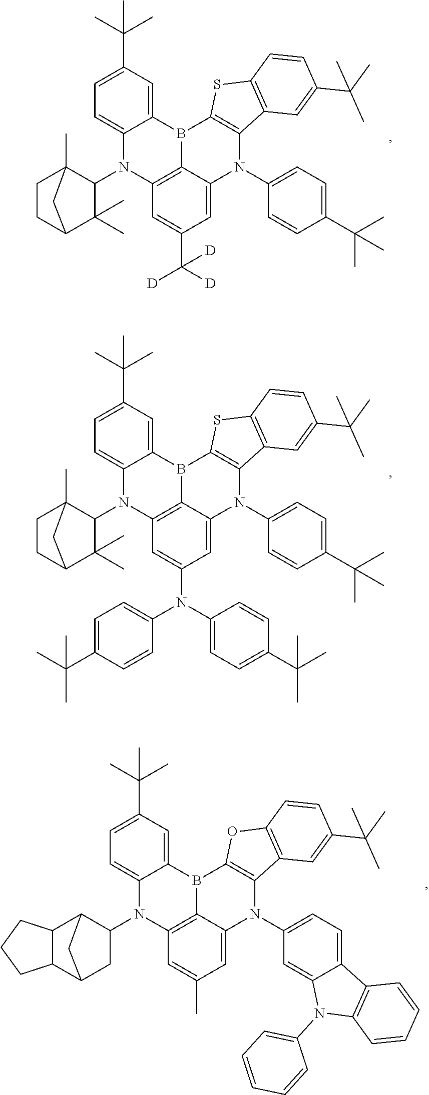 [SMILES: [2H]C([2H])([2H])c1cc2c3c(c1)N(C1C4(C)CCC(C4)C1(C)C)c1ccc(C(C)(C)C)cc1B3c1sc3ccc(C(C)(C)C)cc3c1N2c1ccc(C(C)(C)C)cc1 ; CC(C)(C)c1ccc(N(c2ccc(C(C)(C)C)cc2)c2cc3c4c(c2)N(C2C5(C)CCC(C5)C2(C)C)c2ccc(C(C)(C)C)cc2B4c2sc4ccc(C(C)(C)C)cc4c2N3c2ccc(C(C)(C)C)cc2)cc1 ; Cc1cc2c3c(c1)N(C1CC4CC1C1CCCC41)c1ccc(C(C)(C)C)cc1B3c1oc3ccc(C(C)(C)C)cc3c1N2c1ccc2c3ccccc3n(-c3ccccc3)c2c1]

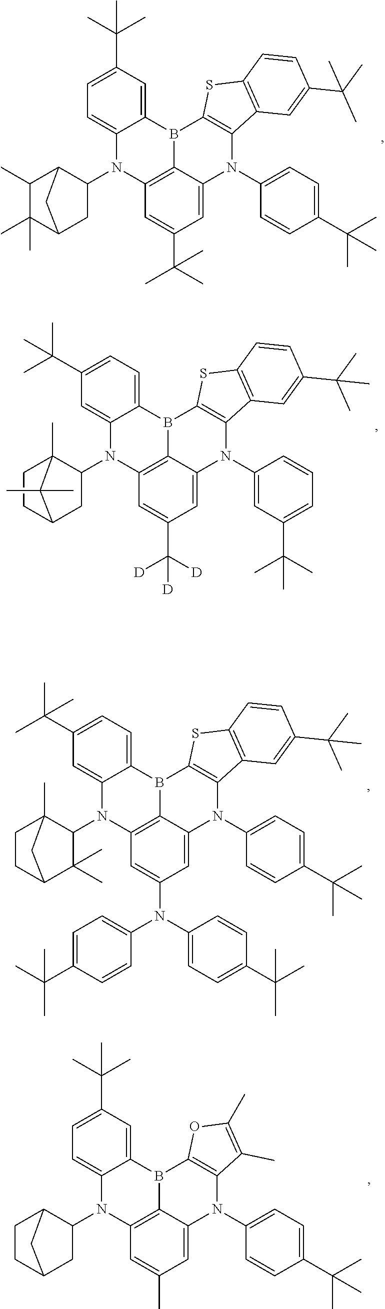

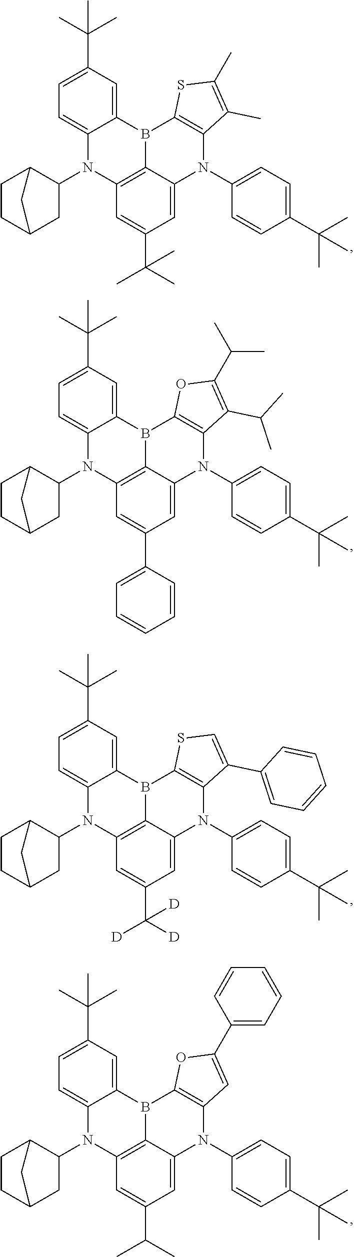

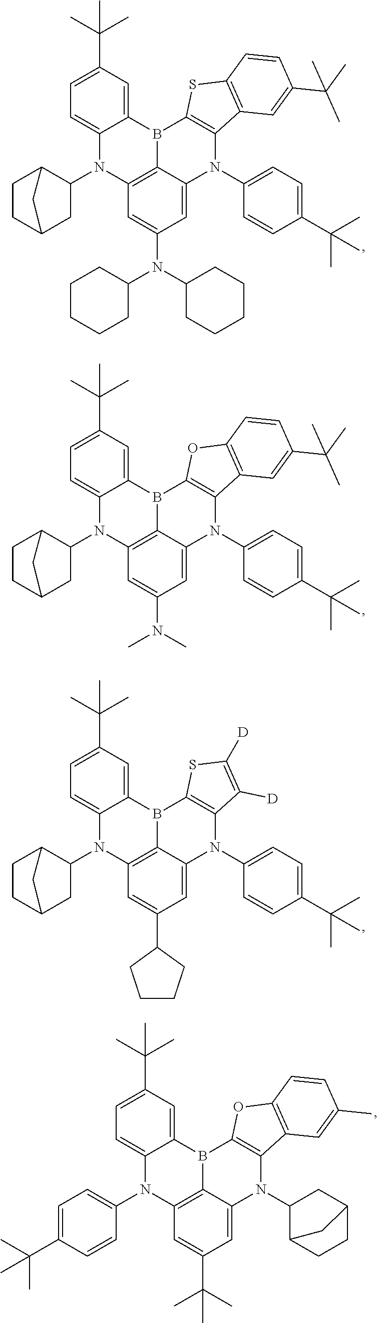

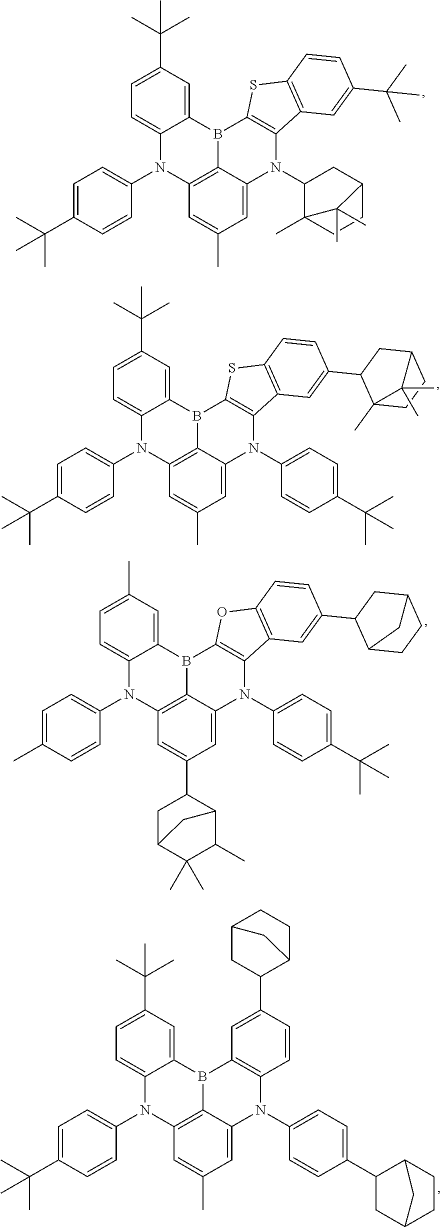

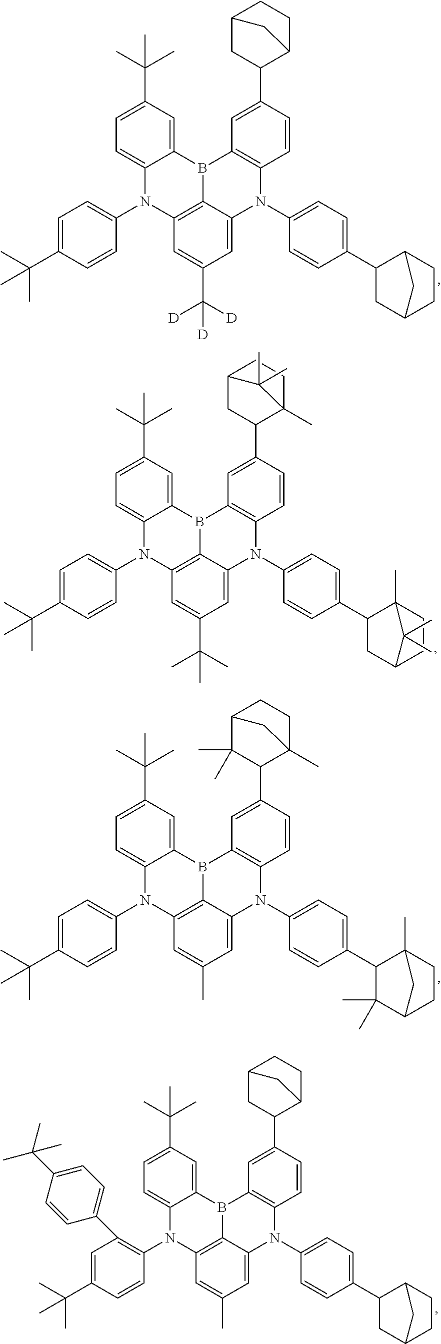

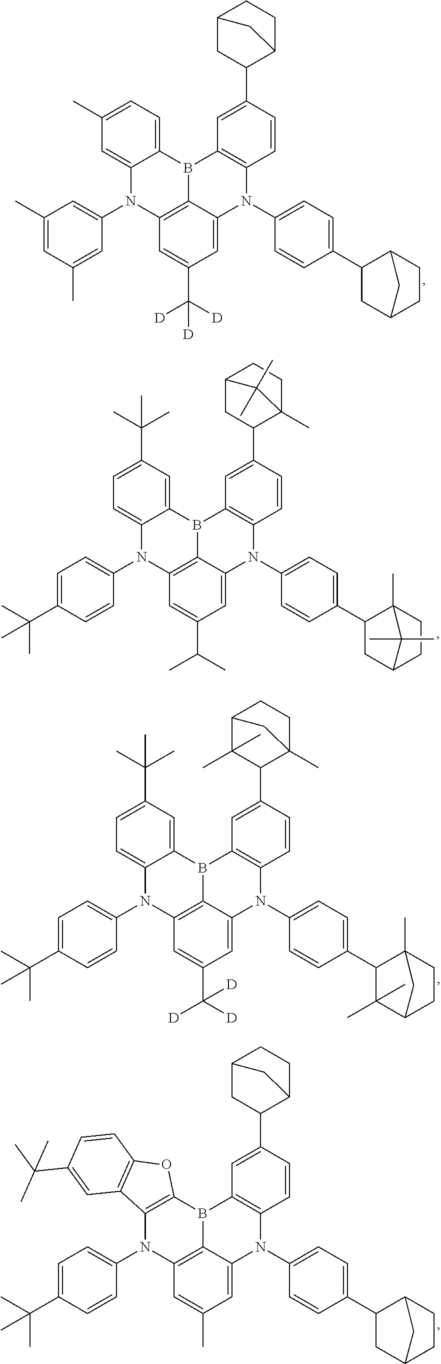

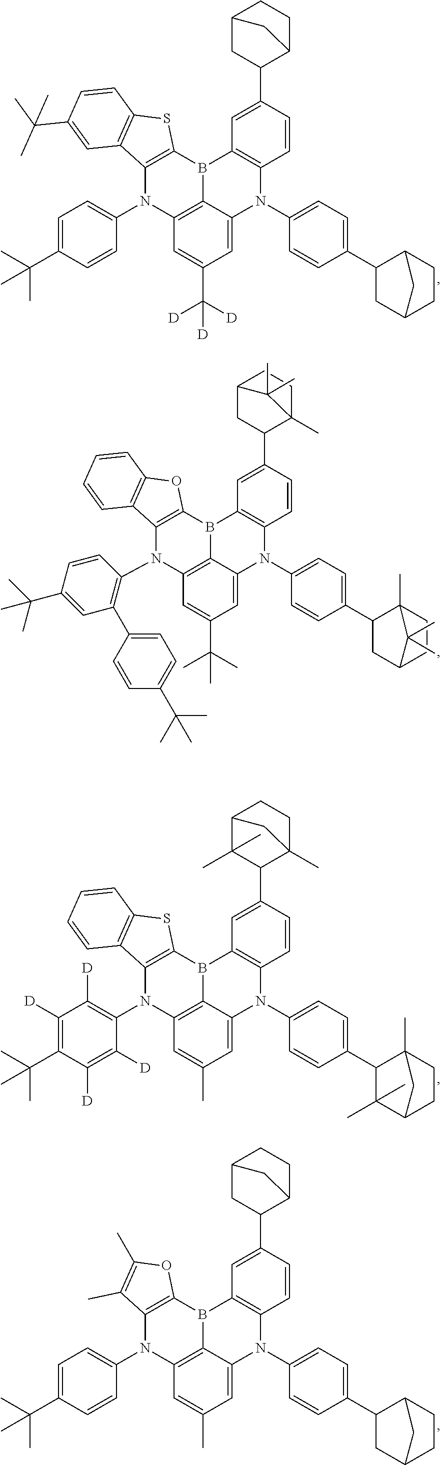

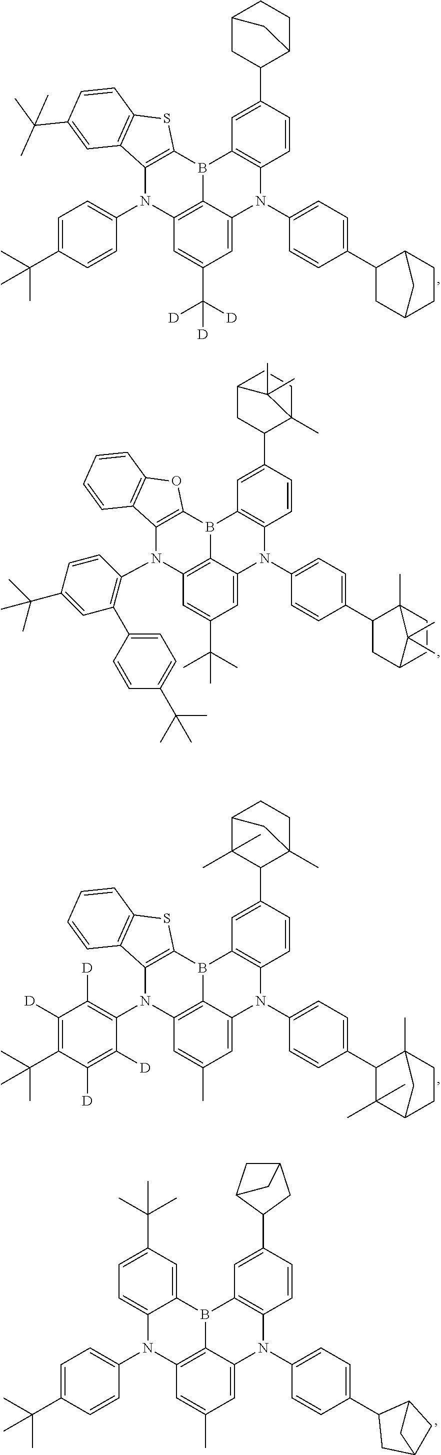

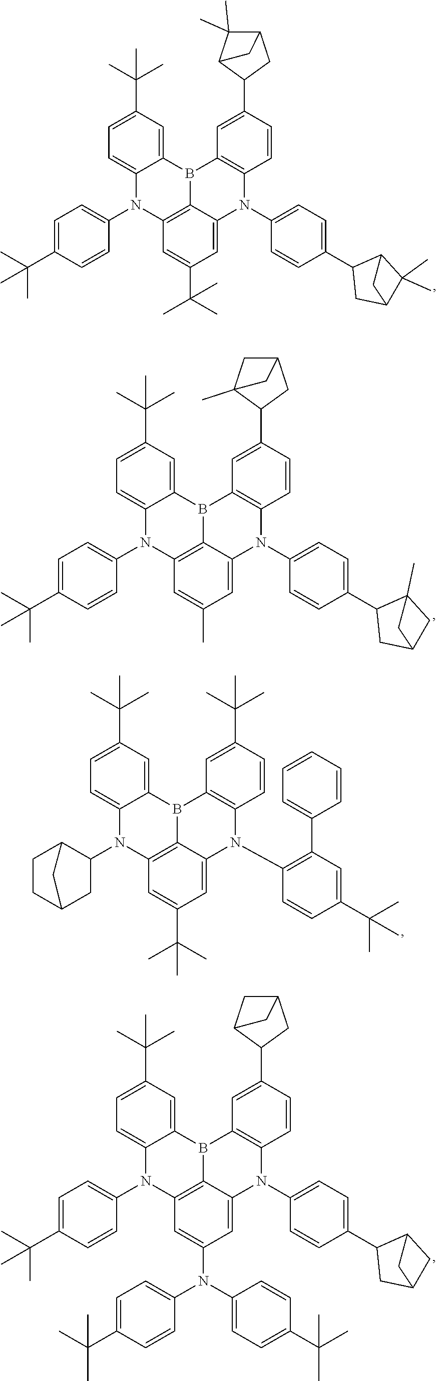

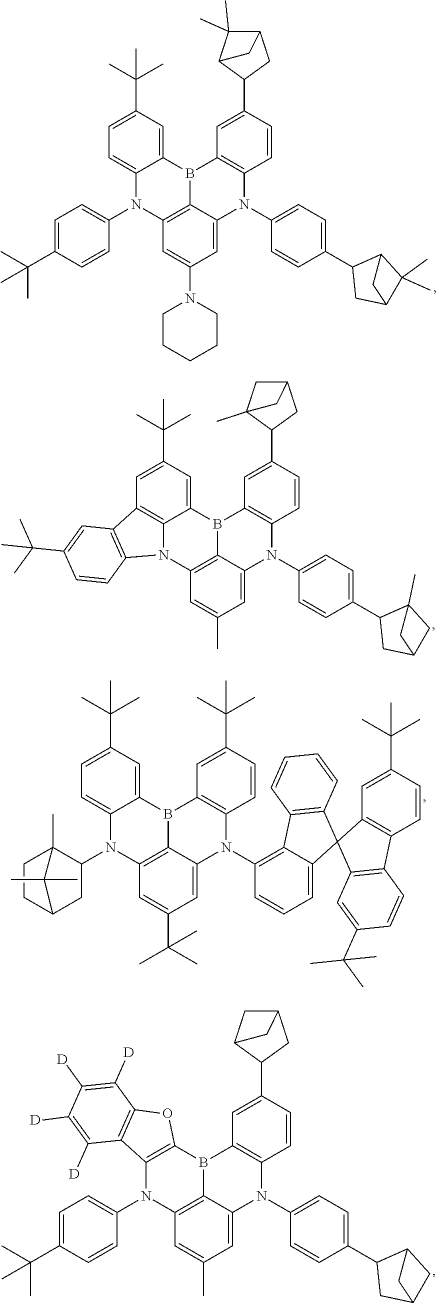

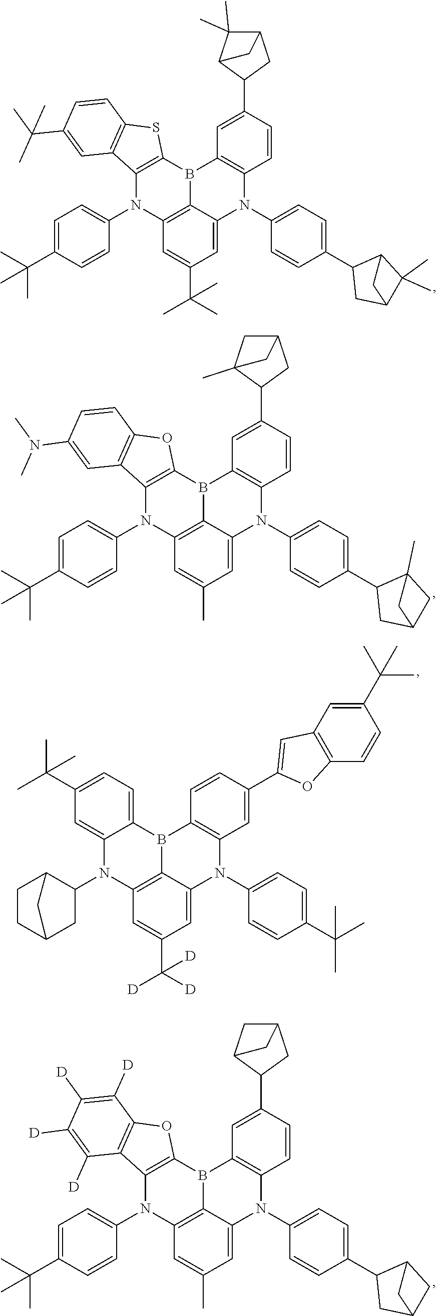

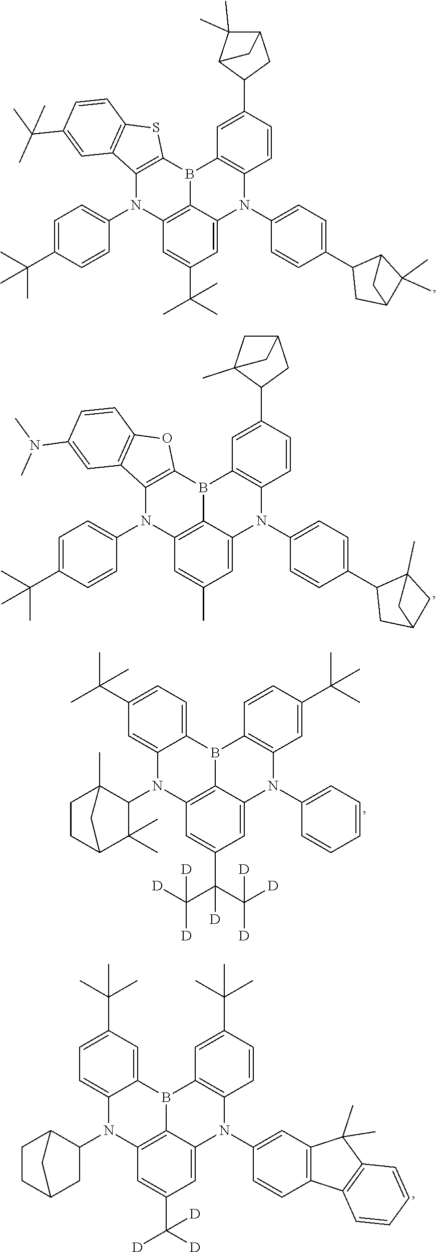

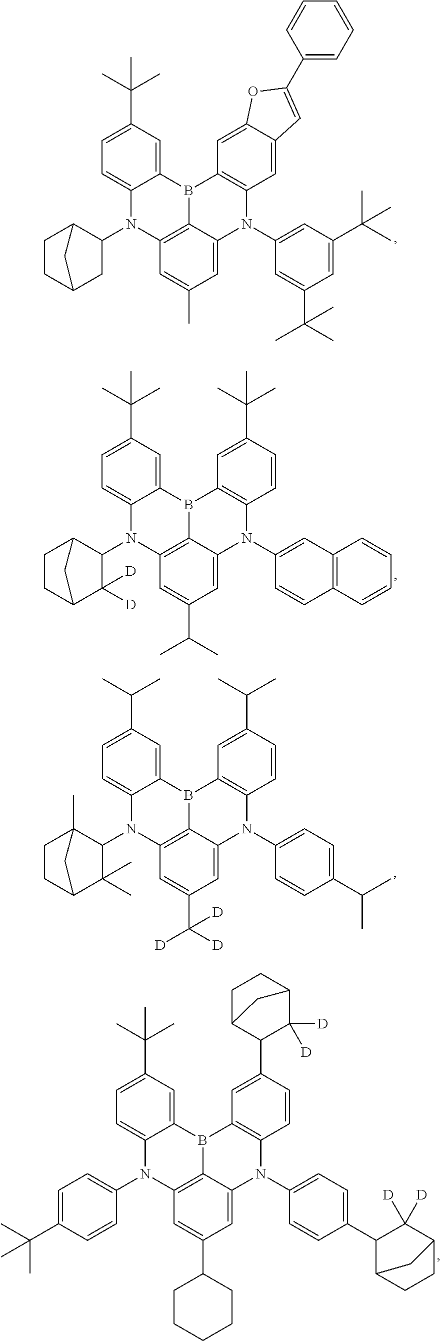

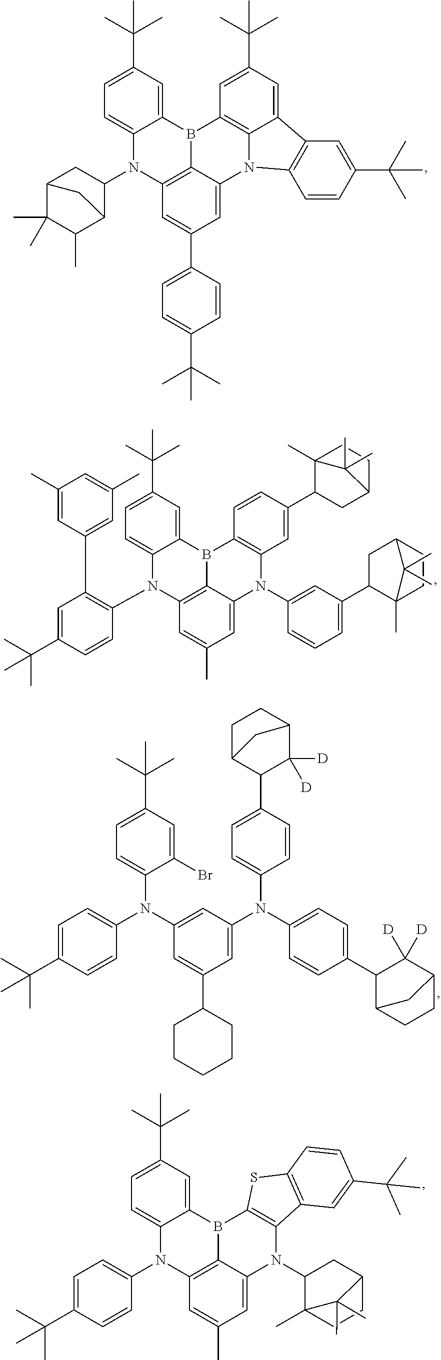

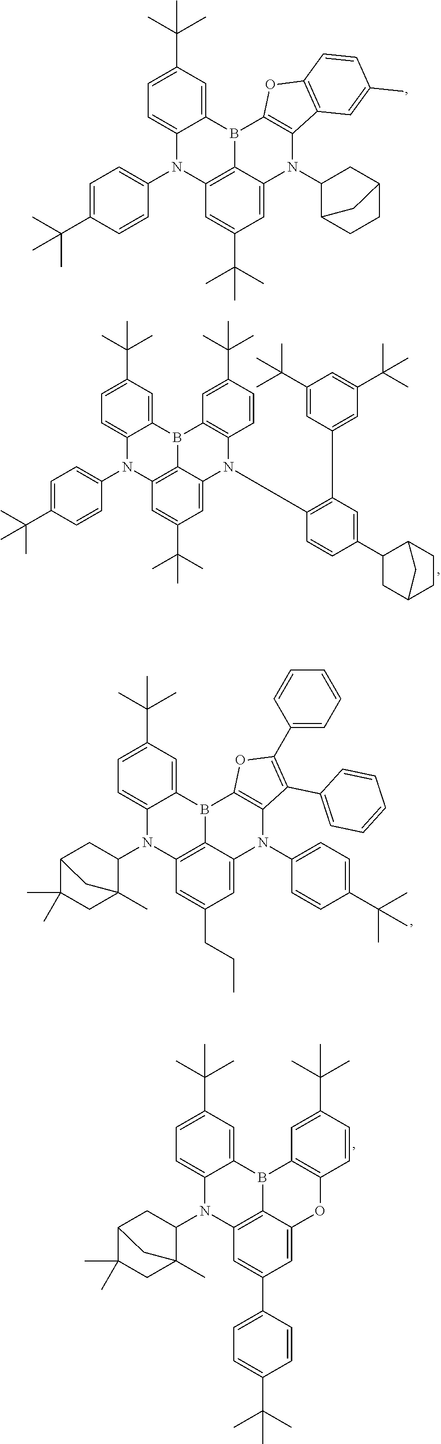

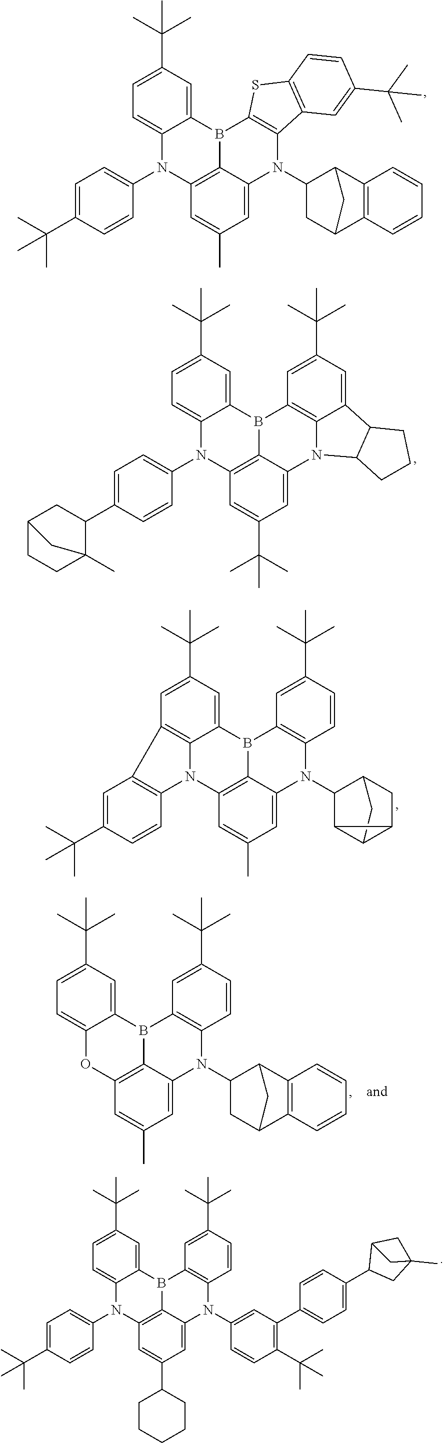

9. An organic electroluminescent device, characterized by comprising an anode, a hole transport region, a luminescent layer, an electron transport region, and a cathode, which are arranged in this order on a substrate plate, wherein the luminescent layer comprises one or more compounds according to claim 1.

10. The organic electroluminescent device according to claim 9, characterized in that the luminescent layer comprises a host material and a doping material, wherein the doping material comprises one or more compounds according to claim 1.
